(19) United States
(12) Patent Application Publication
(10) Pub. No.: US 2023/0350297 A1
(43) Pub. Date: Nov. 2, 2023

(54) METHODS FOR MAKING FLOW CELL SURFACES

(71) Applicant: ILLUMINA CAMBRIDGE LIMITED, Cambridge (GB)

(72) Inventors: Alexandra Szemjonov, Cambridge (GB); Phillippa K. Edge, Cambridge (GB); Alexandre Richez, Cambourne (GB)

(21) Appl. No.: 18/185,208

(22) Filed: Mar. 16, 2023

Related U.S. Application Data
(60) Provisional application No. 63/322,584, filed on Mar. 22, 2022.

(51) Int. Cl. G03F 7/09; G03F 7/075; G03F 7/00; G03F 7/36; G03F 7/031; G03F 7/029

(52) U.S. Cl. CPC G03F 7/094; G03F 7/0757; G03F 7/0002; G03F 7/36; G03F 7/031; G03F 7/029

(57) ABSTRACT

In an example method, an initial depression is defined in a first resin layer of a multi-layer stack including the first resin layer over a second resin layer or a base support. The first resin layer is resistant to silanization in an organic solvent, the second resin layer or the base support is reactive toward silanization in the organic solvent, and the first resin layer and the second resin layer or the base support are orthogonally etchable. A remaining portion of the first resin layer at the initial depression is anisotropically etched, using air or O₂ plasma, through to expose a surface of the second resin layer or the base support and to form a depression. The multi-layer stack is exposed to a silane in the organic solvent to selectively silanizing the surface of the second resin layer or the base support at the depression.

### CROSS REFERENCE TO RELATED APPLICATION

This application claims the benefit of U.S. Provisional Application Ser. No. 63/322,584, filed Mar. 22, 2022, the contents of which is incorporated by reference herein in its entirety.

### REFERENCE TO SEQUENCE LISTING

The Sequence Listing submitted herewith is hereby incorporated by reference in its entirety. The name of the file is ILI230B_IP-2247-US_Sequence_Listing.xml, the size of the file is 15,819 bytes, and the date of creation of the file is Mar. 10, 2023.

### BACKGROUND

Nanoimprinting technology enables the economic and effective production of nanostructures. Nanoimprint lithography employs direct mechanical deformation of a material by a stamp having nanostructures. The material is cured while the stamp is in place to lock the shape of the nanostructures in the material. Nanoimprint lithography has been used to manufacture patterned substrates, and, in many instances, the nanoimprinted material becomes a permanent feature or component of the patterned substrate.

### SUMMARY

Two different resin compositions or a resin composition and a base support are used in the methods disclosed herein to define reactive regions (where sequencing surface chemistry is introduced) and interstitial regions (i.e., regions that are free of sequencing surface chemistry) on a flow cell surface. The cured resin compositions or the cured resin composition and the base support are selected to be orthogonally anisotropically etchable or dissolvable, which enables more complex patterning to be achieved. In some instances, the cured resin compositions are also selected to be orthogonally reactive, which enables the flow cell surface to be selectively functionalized with the sequencing surface chemistry.

With orthogonally anisotropically etchable or dissolvable cured resin compositions, one of the cured resin compositions can be removed while the other of the cured resin compositions remains intact. With the base support and the orthogonally anisotropically etchable or dissolvable cured resin composition, the cured resin compositions can be removed while the base support remains intact. The inclusion of a removable, or sacrificial, resin in the examples disclosed herein eliminates the need for polishing to remove undesired materials. The elimination of polishing renders the workflows less complex.

With orthogonally anisotropically etchable or dissolvable cured resin compositions that are also orthogonally reactive, one of the cured resin compositions can be selectively removed to expose the other cured resin composition. This creates reactive and non-reactive regions of the flow cell surface without having to perform polishing.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1A is a top view of an example flow cell;

FIG. 1B is an enlarged and partially cutaway view of one example of the architecture within a flow channel of the flow cell of FIG. 1A;

FIG. 1C is an enlarged and partially cutaway view of another example of the architecture within a flow channel of the flow cell of FIG. 1A;

FIG. 1D is an enlarged and partially cutaway view of another example of the architecture within a flow channel of the flow cell of FIG. 1A;

FIG. 1E is an enlarged and partially cutaway view of another example of the architecture within a flow channel of the flow cell of FIG. 1A;

FIG. 2A through FIG. 2E are schematic illustrations that together depict an example of a method for making the flow cell architecture of FIG. 1B, where FIG. 2A depicts a working stamp that is to imprint a multi-layer stack, FIG. 2B depicts an initial depression formed in the multi-layer stack of FIG. 2A, FIG. 2C depicts the formation of reactive groups in the depression that is formed after a portion of the initial depression is removed, FIG. 2D depicts the silanization of the depression, and FIG. 2E depicts sequencing surface chemistry attached to the silanized depression;

FIG. 2A through FIG. 2C, FIG. 2F and FIG. 2G are schematic illustrations that together depict an example of a method for making the flow cell architecture of FIG. 1C, where FIG. 2A depicts a working stamp that is to imprint a multi-layer stack, FIG. 2B depicts an initial depression formed in the multi-layer stack of FIG. 2A, FIG. 2C depicts the formation of reactive groups in the depression that is formed after a portion of the initial depression is removed, FIG. 2F depicts the extension of the depression, and FIG. 2G depicts the silanization of the extended depression and the sequencing surface chemistry attached to the silanized, extended depression;

FIG. 3A through FIG. 3D are schematic illustrations that together depict another example of a method for making the flow cell architecture of FIG. 1B, where FIG. 3A depicts a working stamp that is to imprint a multi-layer stack, FIG. 3B depicts an initial depression formed in the multi-layer stack of FIG. 3A, FIG. 3C depicts a depression and adjacent interstitial regions, and FIG. 3D depicts sequencing surface chemistry attached to the depression;

FIG. 3A through FIG. 3C and FIG. 3E are schematic illustrations that together depict another example of a method for making a flow cell architecture similar to that shown in FIG. 1B, where FIG. 3A depicts a working stamp that is to imprint a multi-layer stack, FIG. 3B depicts an initial depression formed in the multi-layer stack of FIG. 3A, FIG. 3C depicts a depression and adjacent interstitial regions, and FIG. 3E depicts sequencing surface chemistry attached to a surface of the depression;

FIG. 3A through FIG. 3C, FIG. 3F, and FIG. 3G are schematic illustrations that together depict another example of a method for making the flow cell architecture of FIG. 1C, where FIG. 3A depicts a working stamp that is to imprint a multi-layer stack, FIG. 3B depicts an initial depression formed in the multi-layer stack of FIG. 3A, FIG. 3C depicts a depression and adjacent interstitial regions, FIG. 3F depicts the extension of the depression, and FIG. 3G depicts sequencing surface chemistry introduced into the extended depression;

FIG. 3A through FIG. 3C, FIG. 3F, and FIG. 3H are schematic illustrations that together depict another example of a method for making a flow cell architecture similar to that shown in FIG. 1C, where FIG. 3A depicts a working stamp that is to imprint a multi-layer stack, FIG. 3B depicts an initial depression formed in the multi-layer stack of FIG. 3A, FIG. 3C depicts a depression and adjacent interstitial regions, FIG. 3F depicts the extension of the depression, and FIG. 3H depicts sequencing surface chemistry attached to a surface of the extended depression;

FIG. 4A through FIG. 4E are schematic illustrations that together depict another example of a method for making the flow cell architecture of FIG. 1D, where FIG. 4A depicts a working stamp that is to imprint a multi-layer stack including a sacrificial resin layer over a hydrophobic layer, FIG. 4B depicts an initial depression formed in the sacrificial resin layer, FIG. 4C depicts a depression and an activated surface of the hydrophobic layer in the depression, FIG. 4D depicts the removal of the sacrificial resin layer, and FIG. 4E depicts sequencing surface chemistry introduced onto the activated surface of the hydrophobic layer;

FIG. 4A through FIG. 4D and FIG. 4F are schematic illustrations that together depict another example of a method for making a flow cell architecture similar to that shown in FIG. 1D, where FIG. 4A depicts a working stamp that is to imprint a multi-layer stack including a sacrificial resin layer over a hydrophobic layer, FIG. 4B depicts an initial depression formed in the sacrificial resin layer, FIG. 4C depicts a depression and an activated surface of the hydrophobic layer in the depression, FIG. 4D depicts the removal of the sacrificial resin layer, and FIG. 4F depicts silanization of the activated surface of the hydrophobic layer and the addition of sequencing surface chemistry introduced onto the silanized surface of the hydrophobic layer;

FIG. 4A, FIG. 4B, FIG. 4C, FIG. 4G, and FIG. 4H are schematic illustrations that together depict another example of a method for making the flow cell architecture of FIG. 1D, where FIG. 4A depicts a working stamp that is to imprint a multi-layer stack including a sacrificial resin layer over a hydrophobic layer, FIG. 4B depicts an initial depression formed in the sacrificial resin layer, FIG. 4C depicts a depression and an activated surface of the hydrophobic layer in the depression, FIG. 4G depicts a polymeric hydrogel applied cover the sacrificial resin layer and the activated surface of the hydrophobic layer, and FIG. 4H depicts removal of the sacrificial resin layer and primers attached to the remaining polymeric hydrogel;

FIG. 5A through FIG. 5E are schematic illustrations that together depict an example of a method for making the flow cell architecture of FIG. 1E, where FIG. 5A depicts a working stamp that is to imprint a multi-layer stack, FIG. 5B depicts a depression formed in the multi-layer stack of FIG. 5A, FIG. 5C depicts a resin layer applied over the multi-layer stack, including in the depression, FIG. 5D depicts the removal of some of the resin layer so that interstitial regions are exposed, and FIG. 5E depicts the depicts the silanization of the remaining resin layer and sequencing surface chemistry surface chemistry attached to the silanized resin layer;

FIG. 6 is a graph depicting the normalized median intensity (Y axis) for two example sacrificial resins and a comparative resin before and after silanization;

FIG. 7A through FIG. 7D are scanning electron micrograph (SEM) images of a patterned sacrificial acrylate resin over an epoxy siloxane resin after being exposed to air plasma etching for different time periods;

FIG. 8A through FIG. 8D are scanning electron micrograph (SEM) images of a patterned sacrificial fluorinated resin over an epoxy siloxane resin after being exposed to air plasma etching for different time periods;

FIG. 9 is a graph depicting the normalized median intensity (Y axis) for the structures shown in FIG. 8A through FIG. 8C and for a comparative structure;

FIGS. 10A and 10B are black and white reproductions of high resolution fluorescent images of different portions of the structure including the patterned sacrificial fluorinated resin over the epoxy siloxane resin after being solution silanized and reacted with a fluorescent marker;

FIG. 11 is a graph depicting the Fourier transform infrared (FTIR) results for two example thiol-ene resins, for one of the thiol-ene resins after 30 seconds of air plasma ashing, and for a comparative acrylate resin; and

FIG. 12 is a black and white reproduction of a high resolution fluorescent image of a portion of the structure including a patterned sacrificial acrylate resin over a thiol-ene resin after being reacted with a fluorescent marker.

### DETAILED DESCRIPTION

Examples of the methods disclosed herein utilize two different resin compositions to define reactive regions (where sequencing surface chemistry is introduced) and interstitial regions (i.e., regions that are free of sequencing surface chemistry) on a flow cell surface. The cured resin compositions are selected to be orthogonally anisotropically etchable or dissolvable, which enables more complex patterning. In some instances, the cured resin compositions are also selected to be orthogonally reactive, which enables the flow cell surface to be selectively functionalized with the sequencing surface chemistry.

### Definitions

It is to be understood that terms used herein will take on their ordinary meaning in the relevant art unless specified otherwise. Several terms used herein and their meanings are set forth below.

The singular forms “a”, “an”, and “the” include plural referents unless the context clearly dictates otherwise.

The terms comprising, including, containing and various forms of these terms are synonymous with each other and are meant to be equally broad.

The terms top, bottom, lower, upper, on, etc. are used herein to describe the flow cell and/or the various components of the flow cell. It is to be understood that these directional terms are not meant to imply a specific orientation, but are used to designate relative orientation between components. The use of directional terms should not be interpreted to limit the examples disclosed herein to any specific orientation(s).

The terms first, second, etc. also are not meant to imply a specific orientation or order, but rather are used to distinguish one component from another.

It is to be understood that the ranges provided herein include the stated range and any value or sub-range within the stated range, as if such values or sub-ranges were explicitly recited. For example, a range of about 400 nm to about 1 μm (1000 nm), should be interpreted to include not only the explicitly recited limits of about 400 nm to about 1 μm, but also to include individual values, such as about 708 nm, about 945.5 nm, etc., and sub-ranges, such as from about 425 nm to about 825 nm, from about 550 nm to about 940 nm, etc. Furthermore, when “about” and/or “substantially” are/is utilized to describe a value, they are meant to encompass minor variations (up to +/−10%) from the stated value.

An “acrylamide monomer” is a monomer with the structure

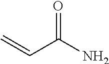

or a monomer including an acrylamide group. Examples of the monomer including an acrylamide group include azido acetamido pentyl acrylamide:

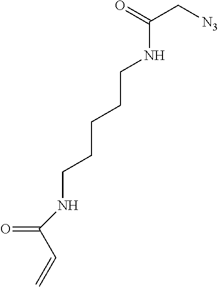 [SMILES: C=CC(=O)NCCCCCNC(=O)CN=[N+]=[N-]]

### and N-isopropylacrylamide:

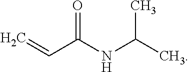

Other acrylamide monomers may be used.

The terms “activate” and “activation” as used herein, refers to a process that generates reactive groups at the surface of a resin layer or a base support. Activation may be accomplished using silanization and/or plasma ashing. While some of the figures do not depict a separate silanized layer or —OH groups from plasma ashing, it is to be understood that activation generates a silanized layer or —OH groups at the surface of the activated support or layer to covalently attach the functionalized layers to the underlying support or layer.

An aldehyde, as used herein, is an organic compound containing a functional group with the structure —CHO, which includes a carbonyl center (i.e., a carbon double-bonded to oxygen) with the carbon atom also bonded to hydrogen and an R group, such as an alkyl or other side chain. The general structure of an aldehyde is:

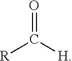

As used herein, “alkyl” refers to a straight or branched hydrocarbon chain that is fully saturated (i.e., contains no double or triple bonds). The alkyl group may have 1 to 20 carbon atoms. Example alkyl groups include methyl, ethyl, propyl, isopropyl, butyl, isobutyl, tertiary butyl, pentyl, hexyl, and the like. As an example, the designation “C1-4 alkyl” indicates that there are one to four carbon atoms in the alkyl chain, i.e., the alkyl chain is selected from the group consisting of methyl, ethyl, propyl, iso-propyl, n-butyl, isobutyl, sec-butyl, and t-butyl.

As used herein, “alkenyl” refers to a straight or branched hydrocarbon chain containing one or more double bonds. The alkenyl group may have 2 to 20 carbon atoms. Example alkenyl groups include ethenyl, propenyl, butenyl, pentenyl, hexenyl, and the like.

As used herein, “alkyne” or “alkynyl” refers to a straight or branched hydrocarbon chain containing one or more triple bonds. The alkynyl group may have 2 to 20 carbon atoms.

As used herein, “aryl” refers to an aromatic ring or ring system (i.e., two or more fused rings that share two adjacent carbon atoms) containing only carbon in the ring backbone. When the aryl is a ring system, every ring in the system is aromatic. The aryl group may have 6 to 18 carbon atoms. Examples of aryl groups include phenyl, naphthyl, azulenyl, and anthracenyl.

An “amine” or “amino” functional group refers to an —NRₐR_{b} group, where Rₐ and R_{b} are each independently selected from hydrogen

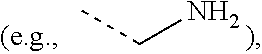

C1-6 alkyl, C2-6 alkenyl, C2-6 alkynyl, C3-7 carbocycle, C6-10 aryl, 5-10 membered heteroaryl, and 5-10 membered heterocyclyl, as defined herein.

As used herein, the term “attached” refers to the state of two things being joined, fastened, adhered, connected or bound to each other, either directly or indirectly. For example, a nucleic acid can be attached to a functionalized polymer by a covalent or non-covalent bond. A covalent bond is characterized by the sharing of pairs of electrons between atoms. A non-covalent bond is a physical bond that does not involve the sharing of pairs of electrons and can include, for example, hydrogen bonds, ionic bonds, van der Waals forces, hydrophilic interactions and hydrophobic interactions.

An “azide” or “azido” functional group refers to —N₃.

As used herein, a “bonding region” refers to an area of a patterned structure that is to be bonded to another material, which may be, as examples, a spacer layer, a lid, another patterned structure, etc., or combinations thereof (e.g., a spacer layer and a lid, or a spacer layer and another patterned structure). The bond that is formed at the bonding region may be a chemical bond (as described herein), or a mechanical bond (e.g., using a fastener, etc.).

As used herein, “carbocycle” means a non-aromatic cyclic ring or ring system containing only carbon atoms in the ring system backbone. When the carbocycle is a ring system, two or more rings may be joined together in a fused, bridged or spiro-connected fashion. Carbocycles may have any degree of saturation, provided that at least one ring in a ring system is not aromatic. Thus, carbocycles include cycloalkyls, cycloalkenyls, and cycloalkynyls. The carbocycle group may have 3 to 20 carbon atoms. Examples of carbocycle rings include cyclopropyl, cyclobutyl, cyclopentyl, cyclohexyl, cyclohexenyl, 2,3-dihydro-indene, bicyclo[2.2.2]octanyl, adamantyl, and spiro[4.4]nonanyl.

As used herein, the term “carboxylic acid” or “carboxyl” as used herein refers to —COOH.

As used herein, “cycloalkylene” means a fully saturated carbocycle ring or ring system that is attached to the rest of the molecule via two points of attachment.

As used herein, “cycloalkenyl” or “cycloalkene” means a carbocycle ring or ring system having at least one double bond, wherein no ring in the ring system is aromatic. Examples include cyclohexenyl or cyclohexene and norbornenyl or norbornene. Also as used herein, “heterocycloalkenyl” or “heterocycloalkene” means a carbocycle ring or ring system with at least one heteroatom in ring backbone, having at least one double bond, wherein no ring in the ring system is aromatic.

As used herein, “cycloalkynyl” or “cycloalkyne” means a carbocycle ring or ring system having at least one triple bond, wherein no ring in the ring system is aromatic. An example is cyclooctyne. Another example is bicyclononyne. Also as used herein, “heterocycloalkynyl” or “heterocycloalkyne” means a carbocycle ring or ring system with at least one heteroatom in ring backbone, having at least one triple bond, wherein no ring in the ring system is aromatic.

The term “depositing,” as used herein, refers to any suitable application technique, which may be manual or automated, and, in some instances, results in modification of the surface properties. Generally, depositing may be performed using vapor deposition techniques, coating techniques, grafting techniques, or the like. Some specific examples include chemical vapor deposition (CVD), spray coating (e.g., ultrasonic spray coating), spin coating, dunk or dip coating, doctor blade coating, puddle dispensing, flow through coating, aerosol printing, screen printing, microcontact printing, inkjet printing, or the like.

As used herein, the term “depression” refers to a discrete concave feature in a base support or a layer (which may be part of a multi-layer stack) having a surface opening that is at least partially surrounded by interstitial region(s) of the base support or the layer. Depressions can have any of a variety of shapes at their opening in a surface including, as examples, round, elliptical, square, polygonal, star shaped (with any number of vertices), etc. The cross-section of a depression taken orthogonally with the surface can be curved, square, polygonal, hyperbolic, conical, angular, etc. As examples, the depression can be a well. The depression may also have more complex architectures, such as ridges, step features, etc.

The term “each,” when used in reference to a collection of items, is intended to identify an individual item in the collection, but does not necessarily refer to every item in the collection. Exceptions can occur if explicit disclosure or context clearly dictates otherwise.

The term “epoxy” (also referred to as a glycidyl or oxirane group) as used herein refers to

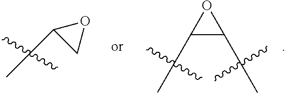

An “epoxy functionalized silsesquioxane” includes a silsesquioxane core that is functionalized with epoxy groups. As used herein, the term “silsesquioxane” refers to a chemical composition that is a hybrid intermediate (RSiO_{1.5}) between that of silica (SiO₂) and silicone (R₂SiO). An example silsesquioxane includes a polyhedral oligomeric silsesquioxane, (commercially available under the tradename FOSS® from Hybrid Plastics Inc.). An example of polyhedral oligomeric silsesquioxane can be that described in Kehagias et al., Microelectronic Engineering 86 (2009), pp. 776-778, which is incorporated by reference in its entirety. The composition is an organosilicon compound with the chemical formula [RSiO_{3/2}]ₙ, where n is an even integer ranging from 6 to 14 and at least some of the R groups are epoxy groups. The resin composition disclosed herein may include one or more different cage or core silsesquioxane structures as monomeric units. In some examples, all of the R groups of the polyhedral oligomeric silsesquioxane are epoxy groups. An example of this type of epoxy functionalized silsesquioxane is glycidyl polyhedral oligomeric silsesquioxane having the structure:

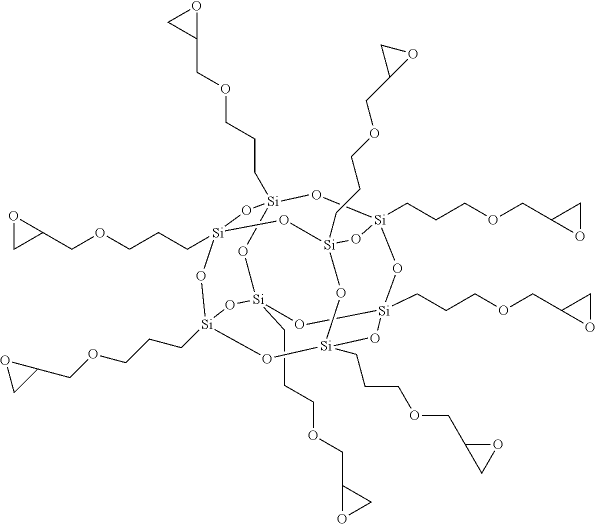 [SMILES: C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

Another example of this type of epoxy functionalized silsesquioxane is epoxycyclohexyl ethyl functionalized polyhedral oligomeric silsesquioxane having the structure:

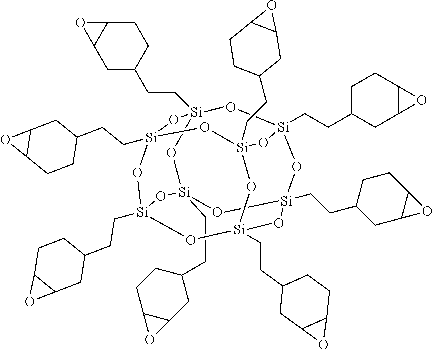 [SMILES: C1CC2OC2CC1CC[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1]

As used herein, the term “flow cell” is intended to mean a vessel having a flow channel where a reaction can be carried out, an inlet for delivering reagent(s) to the flow channel, and an outlet for removing reagent(s) from the flow channel. In some examples, the flow cell accommodates the detection of the reaction that occurs in the flow cell. For example, the flow cell can include one or more transparent surfaces allowing for the optical detection of arrays, optically labeled molecules, or the like.

As used herein, a “flow channel” or “channel” may be an area defined between two bonded components, which can selectively receive a liquid sample. In some examples, the flow channel may be defined between two patterned structures, and thus may be in fluid communication with surface chemistry of the patterned structures. In other examples, the flow channel may be defined between a patterned structure and a lid, and thus may be in fluid communication with surface chemistry of the patterned structures.

As used herein, “heteroaryl” refers to an aromatic ring or ring system (i.e., two or more fused rings that share two adjacent atoms) that contain(s) one or more heteroatoms, that is, an element other than carbon, including but not limited to, nitrogen, oxygen and sulfur, in the ring backbone. When the heteroaryl is a ring system, every ring in the system is aromatic. The heteroaryl group may have 5-18 ring members.

As used herein, “heterocycle” means a non-aromatic cyclic ring or ring system containing at least one heteroatom in the ring backbone. Heterocycles may be joined together in a fused, bridged or spiro-connected fashion. Heterocycles may have any degree of saturation provided that at least one ring in the ring system is not aromatic. In the ring system, the heteroatom(s) may be present in either a non-aromatic or aromatic ring. The heterocycle group may have 3 to 20 ring members (i.e., the number of atoms making up the ring backbone, including carbon atoms and heteroatoms). In some examples, the heteroatom(s) are O, N, or S.

The term “hydrazine” or “hydrazinyl” as used herein refers to a —NHNH₂ group.

As used herein, the term “hydrazone” or “hydrazonyl” as used herein refers to a

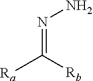

group in which Rₐ and R_{b} are each independently selected from hydrogen, C1-6 alkyl, C2-6 alkenyl, C2-6 alkynyl, C3-7 carbocycle, C6-10 aryl, 5-10 membered heteroaryl, and 5-10 membered heterocycle, as defined herein.

As used herein, “hydroxy” or “hydroxyl” refers to an —OH group.

As used herein, the term “interstitial region” refers to an area, e.g., of a base support or a layer that separates depressions (concave regions) or pads. For example, an interstitial region can separate one depression or pad of an array from another depression or pad of the array. The two depressions or pads that are separated from each other can be discrete, i.e., lacking physical contact with each other. In many examples, the interstitial region is continuous, whereas the depressions or pads are discrete, for example, as is the case for a plurality of depressions defined in or a plurality of pads defined over an otherwise continuous surface. In other examples, the interstitial regions and the features are discrete, for example, as is the case for a plurality of depressions in the shape of trenches, which are separated by respective interstitial regions. The separation provided by an interstitial region can be partial or full separation. Interstitial regions may have a surface material that differs from a material in the depressions or a material that makes up the pads. For example, depressions can have a polymer and primer set(s) therein, and the interstitial regions can be free of polymer and primer set(s).

“Nitrile oxide,” as used herein, means a “RₐC≡N⁺O⁻” group in which Rₐ is defined herein. Examples of preparing nitrile oxide include in situ generation from aldoximes by treatment with chloramide-T or through action of base on imidoyl chlorides [RC(Cl)═NOH] or from the reaction between hydroxylamine and an aldehyde.

“Nitrone,” as used herein, means a

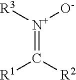

group in which R¹, R², and R³ may be any of the Rₐ and R_{b} groups defined herein, except that R³ is not hydrogen (H).

As used herein, a “nucleotide” includes a nitrogen containing heterocyclic base, a sugar, and one or more phosphate groups. Nucleotides are monomeric units of a nucleic acid sequence. In RNA, the sugar is a ribose, and in DNA, the sugar is a deoxyribose, i.e. a sugar lacking a hydroxyl group that is present at the 2′ position in ribose. The nitrogen containing heterocyclic base (i.e., nucleobase) can be a purine base or a pyrimidine base. Purine bases include adenine (A) and guanine (G), and modified derivatives or analogs thereof. Pyrimidine bases include cytosine (C), thymine (T), and uracil (U), and modified derivatives or analogs thereof. The C-1 atom of deoxyribose is bonded to N-1 of a pyrimidine or N-9 of a purine. A nucleic acid analog may have any of the phosphate backbone, the sugar, or the nucleobase altered. Examples of nucleic acid analogs include, for example, universal bases or phosphate-sugar backbone analogs, such as peptide nucleic acid (PNA).

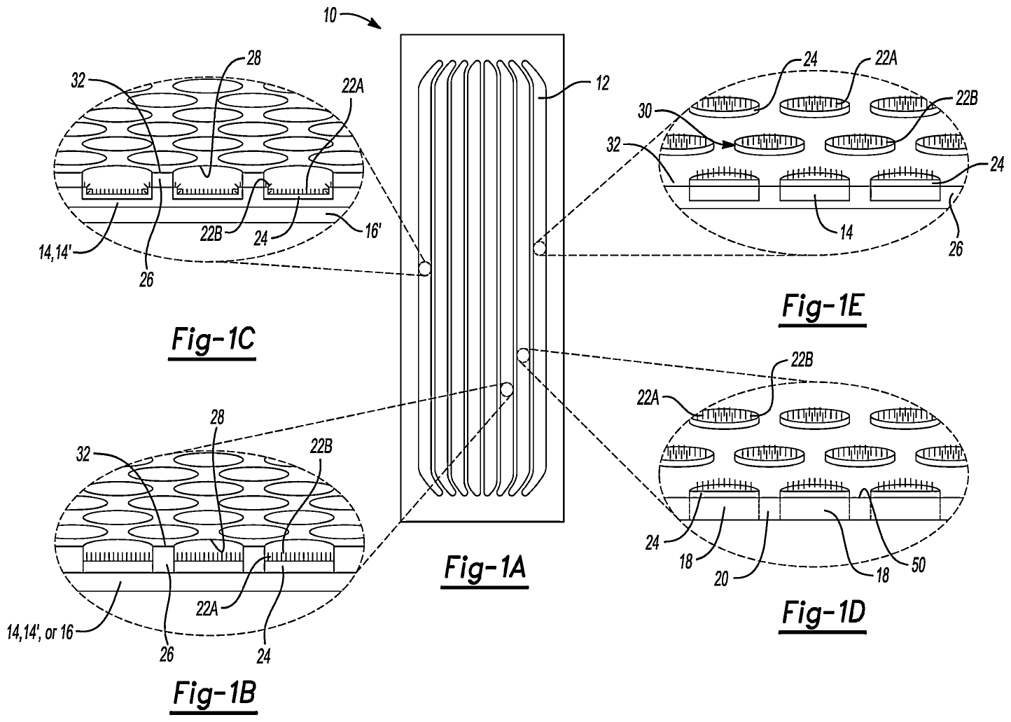

In some examples, the term “over” may mean that one component or material is positioned directly on another component or material. When one is directly on another, the two are in contact with each other. In FIG. 1B, the sacrificial resin layer 26 may be applied over the base support 16 or the second resin layer 14, 14′ so that it is directly on and in contact with the base support 16 or the second resin layer 14, 14′.

In other examples, the term “over” may mean that one component or material is positioned indirectly on another component or material. By indirectly on, it is meant that a gap or an additional component or material may be positioned between the two components or materials. In FIG. 1C, the polymeric hydrogel 24 is positioned over the base support 16′ such that the two are in indirect contact. The second resin layer 14, 14′ is positioned therebetween.

The term “orthogonally anisotropically etchable or dissolvable,” when used to describe two resins, means that the resins are susceptible to different etch conditions or have different dissolution characteristics. Thus, an etchant or organic solvent that is capable of anisotropically etching or dissolving one of the resins is not capable of anisotropically etching or dissolving the other of the resins.

The term “orthogonally reactive,” when used to describe two resins, means that one of the resins includes functional groups that are capable of reacting with and thus attaching surface chemistry, and the other of the resins includes functional groups that are incapable of reacting with and thus attaching the surface chemistry.

A “patterned structure” refers to a base support that includes, or a multi-layer stack with a layer that includes surface chemistry in a pattern, e.g., in depressions or otherwise positioned on the support or layer surface. The surface chemistry may include a polymeric hydrogel and primers (e.g., used for library template capture and amplification) or primers without the polymeric hydrogel. In some examples, the single layer base support or the layer of the multi-layer stack have been exposed to patterning techniques (e.g., anisotropic etching, lithography, etc.) in order to generate the pattern for the surface chemistry. However, the term “patterned structure” is not intended to imply that such patterning techniques have to be used to generate the pattern. The patterned structure may be generated via any of the methods disclosed herein.

As used herein, the “primer” is defined as a single stranded nucleic acid sequence (e.g., single strand DNA). Some primers, referred to herein as amplification primers, serve as a starting point for template amplification and cluster generation. Other primers, referred to herein as sequencing primers, serve as a starting point for DNA synthesis. The 5′ terminus of the primer may be modified to allow a coupling reaction with a functional group of a polymer. The primer length can be any number of bases long and can include a variety of non-natural nucleotides. In an example, the sequencing primer is a short strand, ranging from 10 to 60 bases, or from 20 to 40 bases.

A “spacer layer,” as used herein refers to a material that bonds two components together. In some examples, the spacer layer can be a radiation absorbing material that aids in bonding, or can be put into contact with a radiation absorbing material that aids in bonding.

The term “substrate” refers to the single layer base support or a multi-layer structure upon which surface chemistry is introduced.

“Surface chemistry,” as used herein, refers to i) primers that are, or are to be, attached to a flow cell surface and that are capable of amplifying a library template strand, or ii) the primers and the polymeric hydrogel that attaches the primers to a substrate.

As used herein, the terms “tetrazine” and “tetrazinyl” refer to six-membered heteroaryl group comprising four nitrogen atoms. Tetrazine can be optionally substituted.

“Tetrazole,” as used herein, refer to five-membered heterocyclic group including four nitrogen atoms. Tetrazole can be optionally substituted.

A “thiol” functional group refers to —SH.

Flow Cells

One example of the flow cell 10 is shown in FIG. 1A from a top view. The flow cell 10 may include two patterned structures bonded together, or one patterned structure bonded to a lid.

The patterned structures or the patterned structure and the lid may be attached to one another through a spacer layer (not shown). The spacer layer may be any material that will seal portions of the patterned structures together or portions of the patterned structure and the lid. As examples, the spacer layer may be an adhesive, a radiation-absorbing material that aids in bonding, or the like. In some examples, the spacer layer is the radiation-absorbing material, e.g., KAPTON® black. The patterned structures or the patterned structure and the lid may be bonded using any suitable technique, such as laser bonding, diffusion bonding, anodic bonding, eutectic bonding, plasma activation bonding, glass frit bonding, or others methods known in the art.

Between the two patterned structures or the one patterned structure and the lid is a flow channel 12. The example shown in FIG. 1A includes eight flow channels 12. While eight flow channels 12 are shown, it is to be understood that any number of flow channels 12 may be included in the flow cell 10 (e.g., a single flow channel 12, four flow channels 12, etc.). Each flow channel 12 may be isolated from another flow channel 12 so that fluid introduced into a flow channel 12 does not flow into adjacent flow channel(s) 12. Some examples of the fluids introduced into the flow channel 12 may introduce reaction components (e.g., cleaving fluids, DNA sample, polymerases, sequencing primers, nucleotides, etc.), washing solutions, deblocking agents, etc.

The flow channel 12 may have any desirable shape. In an example, the flow channel 12 has a substantially rectangular configuration with curved ends. The length of the flow channel 12 depends, in part, upon the size of the substrate upon which the patterned structure is formed. The width of the flow channel 12 depends, in part, upon the size of the substrate upon which the patterned structure is formed, the desired number of flow channels 12, the desired space between adjacent channels 12, and the desired space at a perimeter of the patterned structure.

The depth of the flow channel 12 can be as small as a monolayer thick when microcontact, aerosol, or inkjet printing is used to deposit a separate material that defines the flow channel 12 walls. For other examples, the depth of the flow channel 12 can be about 1 μm, about 10 μm, about 50 μm, about 100 μm, or more. In an example, the depth may range from about 10 μm to about 100 μm. In another example, the depth may range from about 10 μm to about 30 μm. In still another example, the depth is about 5 μm or less. It is to be understood that the depth of the flow channel 12 may be greater than, less than or between the values specified above.

Each flow channel 12 is in fluid communication with an inlet and an outlet (not shown). The inlet and outlet of each flow channel 12 may be positioned at opposed ends of the flow cell 10. The inlets and outlets of the respective flow channels 12 may alternatively be positioned anywhere along the length and width of the flow channel 12 that enables desirable fluid flow.

The inlet allows fluids to be introduced into the flow channel 12, and the outlet allows fluid to be extracted from the flow channel 12. Each of the inlets and outlets is fluidly connected to a fluidic control system (including, e.g., reservoirs, pumps, valves, waste containers, and the like) which controls fluid introduction and expulsion.

FIG. 1B, FIG. 1C, FIG. 1D, and FIG. 1E depict different examples of the architecture within the flow channel 12.

Each of the architectures includes a substrate. The substrate varies from architecture to architecture, but includes at least a resin layer 14 (see e.g., FIG. 1B-FIG. 1E), or a base support 16 (see, e.g., FIG. 1B), or a wettable portion 18 of a hydrophobic layer 20 (see FIG. 1D), each of which is capable of supporting the surface chemistry (e.g., primers 22A, 22B, or primers 22A, 22B and polymer hydrogel 24).

An example of the resin layer 14 that is capable of supporting the surface chemistry includes a photocured siloxane-based resin composition.

The photocured siloxane-based resin composition is formed from an epoxy siloxane resin composition including a monomer or cross-linkable copolymer selected from the group consisting of:
i) an epoxy functionalized silsesquioxane (as defined herein);
ii) tetrakis(epoxycyclohexyl ethyl)tetramethyl cyclotetrasiloxane:

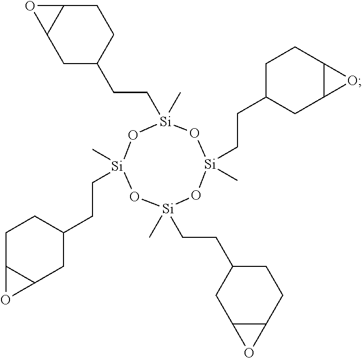 [SMILES: C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

iii) a copolymer of (epoxycyclohexylethyl)methylsiloxane and dimethylsiloxane:

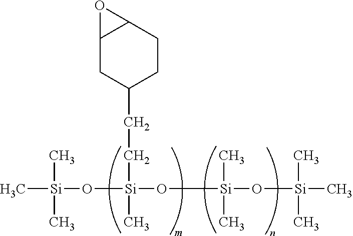

(wherein a ratio of m:n ranges from 8:92 to 10:90);
iv) 1,3-bis[2-(3,4-epoxycyclohexyl) ethyl] tetramethyl disiloxane:

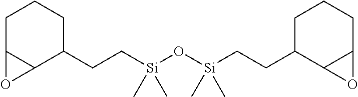 [SMILES: C[Si](C)(CCC1CCCC2OC12)O[Si](C)(C)CCC1CCCC2OC12]

v) 1,3-bis(glycidoxypropyl)tetramethyl disiloxane:

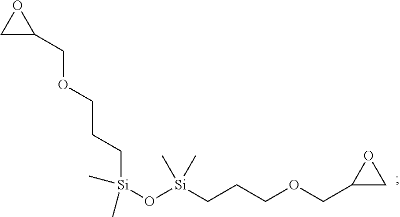 [SMILES: C[Si](C)(CCCOCC1CO1)O[Si](C)(C)CCCOCC1CO1]

and
vi) combinations thereof.

The epoxy siloxane may further include an initiating system selected from the group consisting of a direct photoacid generator and a combination of a free radical photoinitiator and a photoacid generator; an optional surface additive; and a solvent.

The epoxy siloxane resin composition may include one or more cationically curable species, and thus the resin composition also includes an initiating system, such as a direct photoacid generator or a combination of a photoinitiator and a photoacid generator to initiate curing of the monomer(s) or cross-linkable copolymer(s).

The direct photoacid generator does not require a photoinitiator to initiate its decomposition, and thus can directly generate an acid, which, in turn, initiates the polymerization and/or crosslinking of the monomer(s) or cross-linkable copolymer(s). Suitable examples of the direct photoacid generator may be selected from the group consisting of:
i) diaryliodonium hexafluorophosphate:

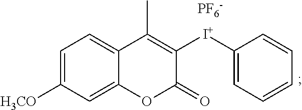

ii) diaryliodonium hexafluoroantimonate:

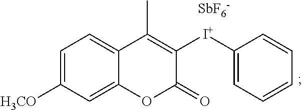 [SMILES: COc1ccc2c(C)c([I+]c3ccccc3)c(=O)oc2c1 ; "SbF6-"]

iii) (cumene)cyclopentadienyliron (II) hexafluorophosphate:

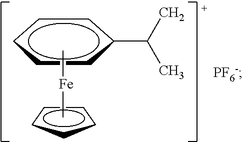

and
iv) combinations thereof. When combinations are used, it is to be understood that any two or more of the listed direct photoacid generators may be used together in the examples of the epoxy siloxane resin composition as long they both are soluble in the solvent used in the resin composition.

In an example, a mass ratio of the monomer(s) or cross-linkable copolymer(s) to the direct photoacid generator ranges from about 99.8:0.2 to 90:10. In another example, a mass ratio of the monomer(s) or cross-linkable copolymer(s) to the direct photoacid generator ranges from about 98:2 to 95:5. In still another example, a mass ratio of the monomer(s) or cross-linkable copolymer(s) to the direct photoacid generator ranges from about 96:4 to 99:1. When lower amounts of the direct photoacid generator are included, the ultraviolet (UV) cure time may have to be increased to allow for complete reaction to form the resin layer 14.

In other examples, the epoxy siloxane resin composition includes the photoinitiator and the photoacid generator. The free radicals generated by the photoinitiator react with the photoacid generator, which decomposes to generate the acid, which, in turn, initiates the polymerization and/or crosslinking of the monomer(s) or cross-linkable copolymer(s).

The free radical photoinitiator may be selected from the group consisting of 2-ethyl-9,10-dimethoxyanthracene, 2,2-dimethoxy-2-phenylacetophenone, 2-ethoxy-2-phenylacetophenone, and a phosphine oxide.

In some examples, the free radical photoinitiator is 2-ethyl-9,10-dimethoxyanthracene:

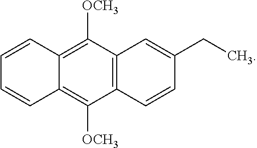 [SMILES: CCc1ccc2c(OC)c3ccccc3c(OC)c2c1]

In other examples, the free radical photoinitiator 2,2-dimethoxy-2-phenylacetophenone:

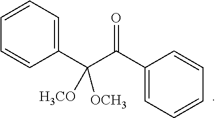 [SMILES: COC(OC)(C(=O)c1ccccc1)c1ccccc1]

In yet other examples, the free radical photoinitiator is 2-ethoxy-2-phenylacetophenone (a.k.a., benzoin ethyl ether):

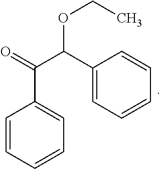 [SMILES: CCOC(C(=O)c1ccccc1)c1ccccc1]

In still other examples, the free radical photoinitiator is the phosphine oxide. When the phosphine oxide is used, it may be selected from the group consisting of:
i) diphenyl(2,4,6-trimethylbenzoyl)phosphine oxide (DPBAPO):

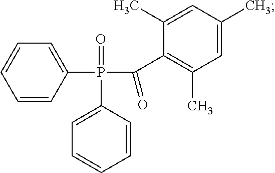 [SMILES: Cc1cc(C)c(C(=O)P(=O)(c2ccccc2)c2ccccc2)c(C)c1]

ii) 2-hydroxy-2-methylpropiophenone or a blend of diphenyl(2,4,6-trimethylbenzoyl)phosphine oxide and 2-hydroxy-2-methylpropiophenone:

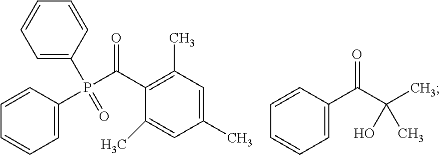

iii) phenylbis(2,4,6-,trimethylbenzoyl)phosphine oxide:

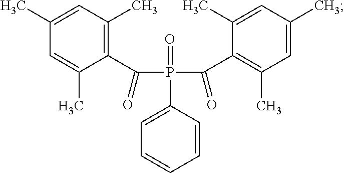 [SMILES: Cc1cc(C)c(C(=O)P(=O)(C(=O)c2c(C)cc(C)cc2C)c2ccccc2)c(C)c1]

iv) ethyl(2,4,6-trimethylbenzoyl)phenylphosphinate:

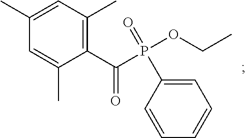 [SMILES: CCOP(=O)(C(=O)c1c(C)cc(C)cc1C)c1ccccc1]

and
v) combinations thereof. When combinations are used, it is to be understood that any two or more of the listed free radical photoinitiators may be used together in this example of the resin composition.

In addition to the free radical photoinitiator, these examples of the epoxy siloxane resin composition also include the photoacid generator (PAG), which is not a direct photoacid generator. It is believed that any suitable photoacid generator that will not undergo undesirable intramolecular interactions with the free radical photoinitiator may be used. Examples of suitable photoacid generators may include benzyl, imino ester, conjugated imino ester, spiropyran, teraylene-based, two-photon, and organometallic PAG systems.

Some specific examples of suitable photoacid generators for use in combination with the photoinitiator are selected from the group consisting of:
i) N-hydroxynaphthalimide triflate:

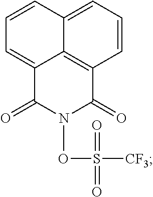 [SMILES: O=C1c2cccc3cccc(c23)C(=O)N1OS(=O)(=O)C(F)(F)F]

ii) triarylsulfonium hexafluorophosphate salts, mixed:

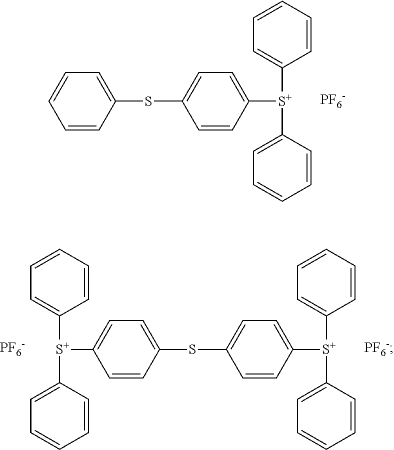

iii) triarylsulfonium hexafluoroantimonate salts, mixed:

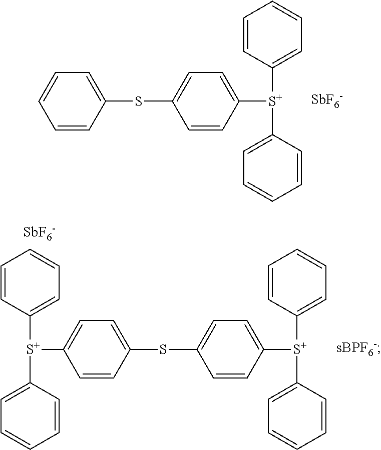

iv) 1-naphthyl diphenylsulfonium triflate (NDS-TF):

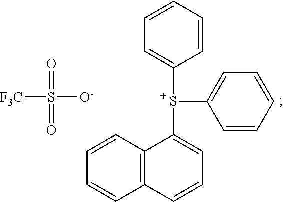 [SMILES: O=S(=O)([O-])C(F)(F)F ; c1ccc([S+](c2ccccc2)c2cccc3ccccc23)cc1]

v) (4-phenylthiophenyl)diphenylsulfonium triflate:

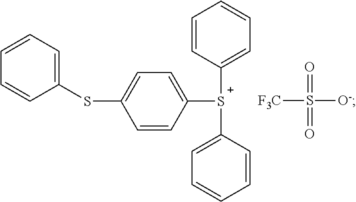

vi) bis-(4-methylphenyl)iodonium hexafluorophosphate (IPF):

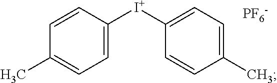

vii) bis(4-tert-butylphenyl)iodonium hexafluorophosphate:

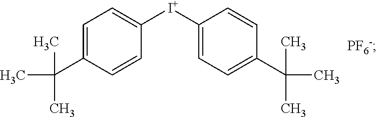

viii) (2-methylphenyl)(2,4,6-trimethylphenyl)iodonium triflate:

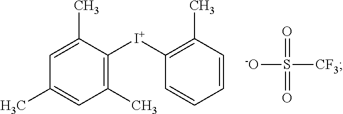

ix) bis(2,4,6-trimethylphenyl)iodonium triflate:

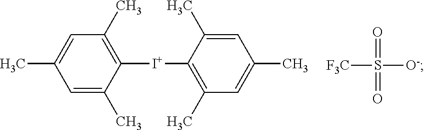

x) bis-(4-dedecylphenyl)iodonium hexafluoroantimonate salt:

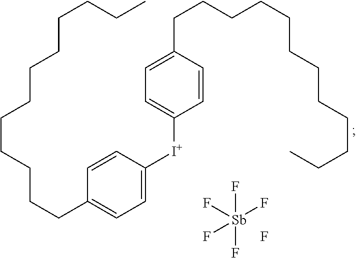

xi) tris-(4-((4-acetylphenyl)thio)phenyl)-sulfonium tetrakis(perfluoro-phenyl)borate (PAG 290):

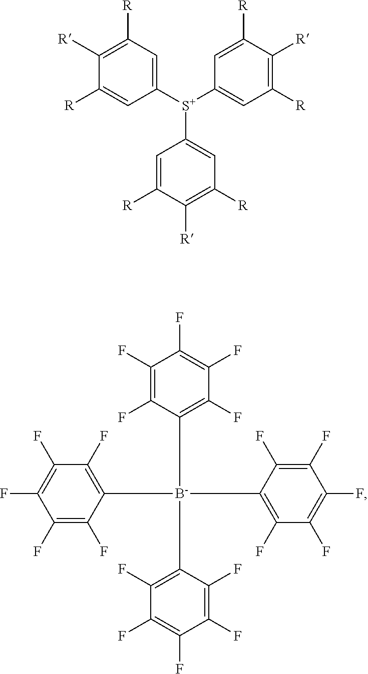

wherein where R is

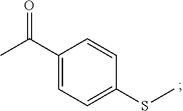

and
xii) combinations thereof. Combinations of the photoacid generators may be used as long as they are soluble in the selected solvent.

In these examples, a mass ratio of the monomer(s) or cross-linkable copolymer(s) to the free radical photoinitiator/photoacid generator combination ranges from about 99.8:0.2 to 90:10. In another example, a mass ratio of the monomer(s) or cross-linkable copolymer(s) to the free radical photoinitiator/photoacid generator combination ranges from about 98:2 to 95:5. In still another example, a mass ratio of the monomer(s) or cross-linkable copolymer(s) to the free radical photoinitiator/photoacid generator combination ranges from about 96:4 to 99:1. When lower amounts of the free radical photoinitiator/photoacid generator combination are included, the UV cure time may have to be increased to allow for complete reaction.

Some examples of the epoxy siloxane resin composition may also include a surface additive. The surface additive can adjust the surface tension of the epoxy siloxane resin composition, which can improve the coatability of the diluted resin composition, promote thin film stability, and/or improve leveling. Examples of surface additives include polyacrylate polymers (such as BYK®-350 available from BYK). The amount of the surface additive may be 3 mass % or less, based on the total mass of the epoxy siloxane resin composition.

The epoxy siloxane resin composition may also include a solvent. The solvent may be added to achieve a desired viscosity for the deposition technique being used to apply the epoxy siloxane resin composition. Examples of the epoxy siloxane resin composition viscosity ranges from about 1.75 mPa to about 2.2 mPa (measured at 25° C.). Examples of suitable solvents include propylene glycol monomethyl ether acetate (PGMEA), toluene, dimethyl sulfoxide (DMSO), tetrahydrofuran (THF), etc. In some examples, the solvent is PGMEA. The total solids concentration of the epoxy siloxane resin composition may range from about 15 mass % to about 60 mass %, and the amount of solvent may range from about 40 mass % to about 85 mass %. Not to be bound by any particular theory, but it is believed that the upper limits may be higher depending upon the respective solubility of the solid component(s) in the solvent that is selected.

As will be described in reference to some of the examples of the method disclosed herein, the epoxy siloxane resin composition is photocured to form the resin layer 14.

The photocured epoxy siloxane resin composition can be etched with a fluorinated plasma (e.g., CF₄ or CF₄/SF₆).

Some of the architectures in the flow cell channel 12 include a base support 16′ in addition to the photocured siloxane-based resin composition 14, or include a base support 16 instead of the photocured siloxane-based resin composition 14.

When used in addition to the photocured siloxane-based resin composition 14, the base support 16′ (e.g., as shown in FIG. 1C) is used as an underlying support structure for the flow cell substrate. Examples of suitable base support 16′ materials in these instances include glass, modified or functionalized glass, plastics (including acrylics, polystyrene and copolymers of styrene and other materials, polypropylene, polyethylene, polybutylene, polyurethanes, polytetrafluoroethylene (such as TEFLON® from Chemours), cyclic olefins/cyclo-olefin polymers (COP) (such as ZEONOR® from Zeon), polyimides, etc.), nylon (polyamides), ceramics/ceramic oxides, silica, fused silica, or silica-based materials, aluminum silicate, silicon and modified silicon (e.g., boron doped p+ silicon), silicon nitride (Si₃N₄), silicon oxide (SiO₂), tantalum pentoxide (Ta₂O₅) or other tantalum oxide(s) (TaOₓ), hafnium oxide (HfO₂), carbon, metals, or the like.

When used in place of the photocured siloxane-based resin composition 14, the base support 16 (e.g., as shown in FIG. 1B) itself is capable of supporting the surface chemistry (e.g., primers 22A, 22B, or primers 22A, 22B and polymer hydrogel 24). In other words, the base support 16 includes or can be activated to include functional groups that can covalently attach to 5′ end linkers of the primers 22A, 22B or to functional groups of the polymeric hydrogel 24). Examples of suitable base support 16 materials in these instances include epoxy silane, glass, modified glass, or functionalized glass.

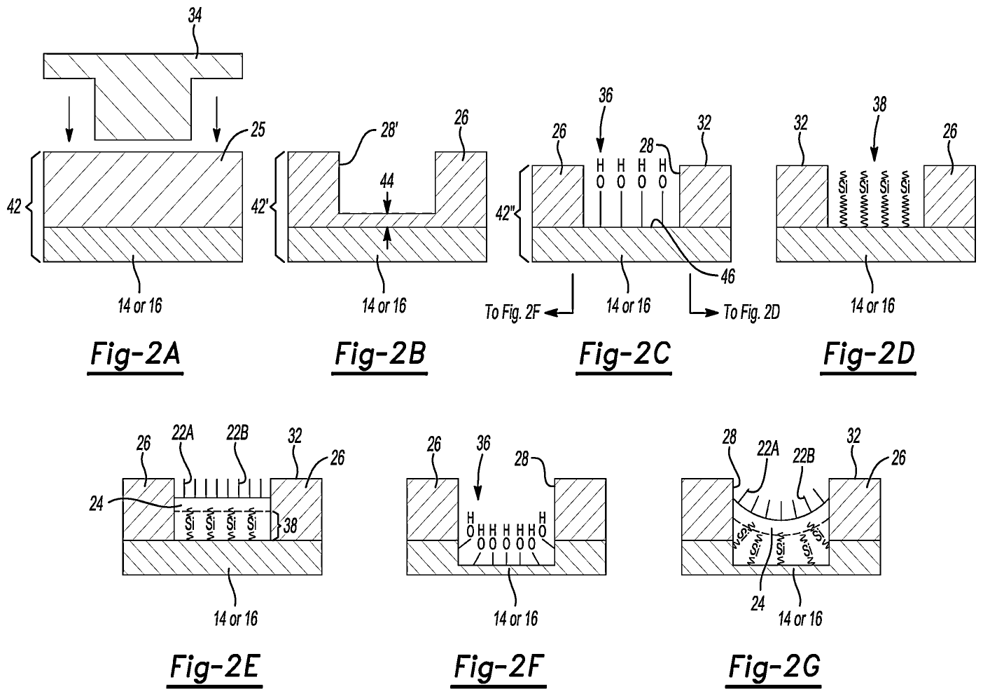

Some of the architectures in the flow cell channel 12 include the resin layer 14′ instead of the resin layer 14. The resin layer 14′ is a photocured thiol-ene resin composition instead of the photocured epoxy siloxane resin composition. While the photocured epoxy siloxane resin composition is reactive toward silanization in an organic solvent (as will be described in reference to FIG. 2A through FIG. 2G), the photocured thiol-ene resin composition is not reactive toward silanization in an organic solvent. Rather, the photocured thiol-ene resin composition includes reactive thiol groups that can be reacted using base catalyzed Michael addition to attached primers 22A, 22B or the polymeric hydrogel 24. The thiol groups remain reactive even after being exposed to air or O₂ plasma.

The photocured thiol-ene resin composition (i.e., resin layer 14′) is formed from a thiol-ene resin composition including from greater than 0 mass % to less than 50 mass %, based on a total monomer content of the thiol-ene resin composition, of an acrylate monomer; from greater than 50 mass % to less than 100 mass % based on the total monomer content of the thiol-ene resin composition, of a thiol monomer selected from the group consisting of:
i) pentaerythritol tetrakis(3-mercaptopropionate):

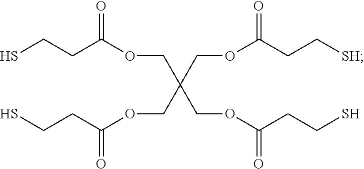 [SMILES: O=C(CCS)OCC(COC(=O)CCS)(COC(=O)CCS)COC(=O)CCS]

ii) 1,4-bis(3-mercaptobutyryloxy)butane; and
iii) trimethylolpropane tris(3-mercaptopropionate);
   a radical photoinitiator; an acidic stabilizer, a radical stabilizer, or combinations thereof;
   an optional surface additive; and a solvent.

Examples of the acrylate monomers for the thiol-ene resin composition include:
i) glycerol dimethacrylate, mixture of isomers:

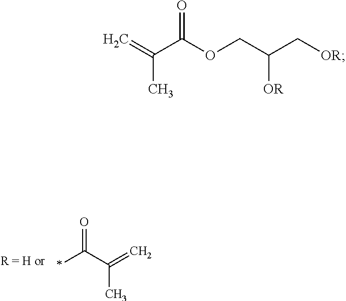

ii) pentaerythritol triacrylate:

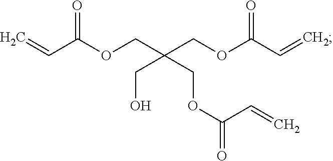 [SMILES: C=CC(=O)OCC(CO)(COC(=O)C=C)COC(=O)C=C]

iii) glycerol 1,3-diglycerolate diacrylate:

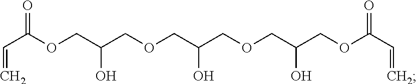 [SMILES: C=CC(=O)OCC(O)COCC(O)COCC(O)COC(=O)C=C]

iv) pentaerythritol tetraacrylate:

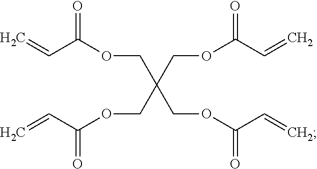 [SMILES: C=CC(=O)OCC(COC(=O)C=C)(COC(=O)C=C)COC(=O)C=C]

and
v) combinations thereof.

An excess of the thiol monomer (relative to the acrylate monomer) is desirable to ensure the presence of functionalizable surface thiol groups.

The thiol-ene resin composition further includes the radical photoinitiator. Any of the free radical photoinitiators described herein for the epoxy siloxane resin composition may be used as the radical photoinitiator in the thiol-ene resin composition. In these examples, a mass ratio of the total acrylate and thiol monomers to the radical photoinitiator ranges from about 99.8:0.2 to 90:10. In another example, a mass ratio of the total acrylate and thiol monomers to the radical photoinitiator ranges from about 98:2 to 95:5. When lower amounts of the free radical photoinitiator/photoacid generator combination are included, the UV cure time may have to be increased to allow for complete reaction.

The thiol-ene resin composition further includes an acidic stabilizer, a radical stabilizer, or combinations thereof. Examples of suitable acid stabilizers include a substituted phenyl:

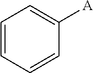

where A is SO₃H, CO₂H, or PO₃H₂; vinyl phosphate:

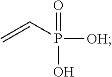

and (2-{[2-(Ethoxycarbonyl)prop-2-en-1-yl]oxy}ethyl)phosphonic acid:

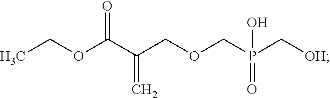

and examples of suitable radical stabilizers include benzene-1,2,3-triol:

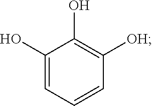

4-methoxyphenol:

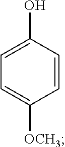

4-tert-butyl-1,2-dihydroxy benzene:

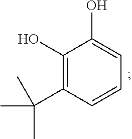

and butylated hydroxytoluene

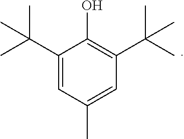 [SMILES: Cc1cc(C(C)(C)C)c(O)c(C(C)(C)C)c1]

A specific example of a suitable acid stabilizer includes phenyl dihydrogen phosphate:

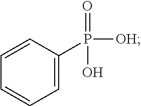

and an example of a suitable radical stabilizer includes benzene-1,2,3-triol:

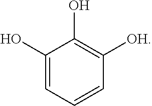

The thiol-ene resin composition may include the surface additive. The surface additive described herein for the epoxy siloxane resin composition may be used as the surface additive in the thiol-ene resin composition in any of the provided amounts.

The thiol-ene resin composition further includes the solvent. Any of the solvents described herein for the epoxy siloxane resin composition may be used as the solvent in the thiol-ene resin composition in any of the provided amounts.

As will be described in reference to some of the examples of the method disclosed herein, the thiol-ene resin composition is photocured to form the resin layer 14′.

In any of the example architectures including the resin layer 14′, the resin layer 14′ may be supported by any example of the base support 16′ (e.g., as shown in FIG. 1C). In this example, the base support 16′ is used as an underlying support structure for the flow cell substrate.

Some of the architectures in the flow cell channel 12 also include a sacrificial resin layer 26 (FIGS. 1B, 1C, and 1E, also referred to herein as the first resin layer). During processing to create the depressions 28 (FIG. 1B and FIG. 1C) or pads 30 (FIG. 1D), the sacrificial resin layer 26 may be anisotropically etched using air or O₂ plasma. It is to be understood that the resin layer 14 is not susceptible to the etchant used for the sacrificial resin layer 26, and the etchant used for the sacrificial resin layer 26 does not deactivate the reactive thiol groups of the resin layer 14′.

Examples of suitable sacrificial resin layers 26 include a photocured acrylate resin composition, a photocured fluorinated resin composition, and a photocured organic epoxy resin composition. Each of these will now be described in detail.

The photocured acrylate resin composition is formed from an acrylate resin composition including an acrylate monomer selected from the group consisting of glycerol dimethacrylate, mixture of isomers; pentaerythritol triacrylate; glycerol 1,3-diglycerolate diacrylate; pentaerythritol tetraacrylate; and combinations thereof; a radical photoinitiator; a surface additive; and a solvent.

Any of the free radical photoinitiators described herein for the epoxy siloxane resin composition may be used as the radical photoinitiator in the acrylate resin composition. In an example of the acrylate resin composition, a mass ratio of the acrylate monomer(s) to the radical initiator ranges from about 99.8:0.2 to 90:10. In another example, a mass ratio of the acrylate monomer(s) to the radical initiator ranges from about 98:2 to 95:5. In still another example, a mass ratio of the acrylate monomer(s) to the radical initiator ranges from about 96:4 to 99:1. When lower amounts of the radical initiator are included, the UV cure time may have to be increased to allow for complete reaction to form the sacrificial resin layer 26.

The surface additive described herein for the epoxy siloxane resin composition may be used as the surface additive in the acrylate resin composition in any of the provided amounts. Moreover, any of the solvents described herein for the epoxy siloxane resin composition may be used as the solvent in the acrylate resin composition in any of the provided amounts.

The photocured fluorinated resin composition is formed from a fluorinated resin composition including a fluorinated monomer selected from the group consisting of a bifunctional polyfluoro-polyethylene-urethane methacrylate: (which is commercially available from Solvay under the tradename FLUOROLINK® MD 700)

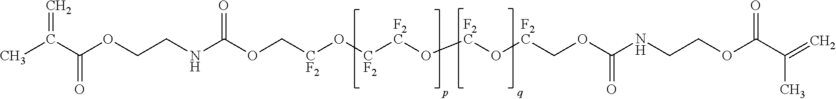

where the ratio of p:q is 2:3 and the weight average molecular weight ranges from about 3,000 g/mol to about 5,000 g/mol; 2,2,3,3,4,4,5,5-octafluoro-1,6-hexanediol diacrylate:

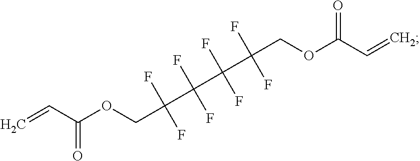 [SMILES: C=CC(=O)OCC(F)(F)C(F)(F)C(F)(F)C(F)(F)COC(=O)C=C]

and combinations thereof; a radical photoinitiator; an optional surface additive; and a solvent.

Any of the free radical photoinitiators described herein for the epoxy siloxane resin composition may be used as the radical photoinitiator in the fluorinated resin composition. In an example of the fluorinated resin composition, a mass ratio of the fluorinated monomer(s) to the radical initiator ranges from about 99.8:0.2 to 90:10. In another example, a mass ratio of the fluorinated monomer(s) to the radical initiator ranges from about 98:2 to 95:5. In still another example, a mass ratio of the fluorinated monomer(s) to the radical initiator ranges from about 96:4 to 99:1. When lower amounts of the radical initiator are included, the UV cure time may have to be increased to allow for complete reaction to form the sacrificial resin layer 26.

The surface additive described herein for the epoxy siloxane resin composition may be used as the surface additive in the fluorinated resin composition in any of the provided amounts. Moreover, any of the solvents described herein for the epoxy siloxane resin composition may be used as the solvent in the fluorinated resin composition in any of the provided amounts. Another suitable solvent for the fluorinated resin composition is butyl acetate. As examples, butyl acetate may be particularly desirable when bifunctional polyfluoro-polyethylene-urethane methacrylate is used as the fluorinated monomer, and PGMEA may be particularly desirable when 2,2,3,3,4,4,5,5-octafluoro-1,6-hexanediol diacrylate is used as the fluorinated monomer.

The photocured organic epoxy resin composition is formed from an organic epoxy resin composition including a monomer or cross-linkable copolymer selected from the group consisting of:
i) trimethylolpropane triglycidyl ether:

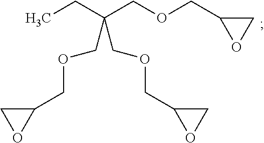 [SMILES: CCC(COCC1CO1)(COCC1CO1)COCC1CO1]

ii) 3,4-epoxycyclohexylmethyl-3,4-epoxycyclo-hexanecarboxylate:

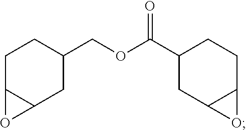 [SMILES: O=C(OCC1CCC2OC2C1)C1CCC2OC2C1]

iii) bis((3,4-epoxycyclohexyl)methyl) adipate:

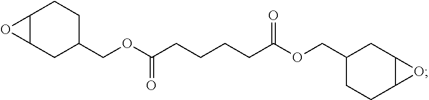 [SMILES: O=C(CCCCC(=O)OCC1CCC2OC2C1)OCC1CCC2OC2C1]

iv) 4-vinyl-1-cyclohexene 1,2-epoxide:

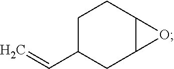

v) vinylcyclohexene dioxide:

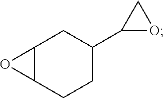

vi) 4,5-epoxytetrahydrophthalic acid diglycidylester:

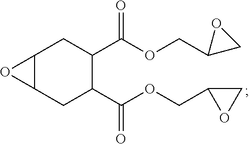 [SMILES: O=C(OCC1CO1)C1CC2OC2CC1C(=O)OCC1CO1]

vii) 1,2-epoxy-3-phenoxypropane:

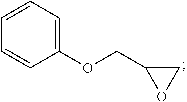 [SMILES: c1ccc(OCC2CO2)cc1]

viii) glycidyl methacrylate:

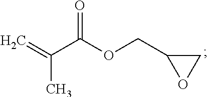

ix) 1,2-epoxyhexadecane:

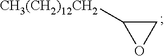

x) poly(ethylene glycol) diglycidylether:

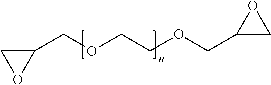

(wherein n ranges from 1 to 100);
xi) pentaerythritol glycidyl ether:

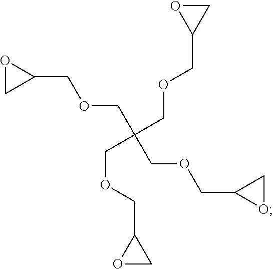 [SMILES: C(OCC(COCC1CO1)(COCC1CO1)COCC1CO1)C1CO1]

xii) diglycidyl 1,2-cyclohexanedicarboxylate:

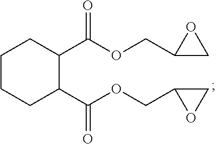 [SMILES: O=C(OCC1CO1)C1CCCCC1C(=O)OCC1CO1]

xiii) tetrahydrophthalic acid diglycidyl ester:

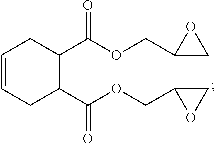 [SMILES: O=C(OCC1CO1)C1CC=CCC1C(=O)OCC1CO1]

and
xiv) combinations thereof; an initiating system selected from the group consisting of a direct photoacid generator and a combination of a free radical photoinitiator and a photoacid generator; and a solvent. In some instances, the organic epoxy resin composition also includes a surface additive.

Any of the direct photoacid generators or the combinations of the free radical photoinitiator and the photoacid generator described herein for the epoxy siloxane resin composition may be used in the organic epoxy resin composition. In an example of the organic epoxy composition, a mass ratio of the monomer(s) or cross-linkable copolymer(s) to the direct photoacid generator or the combination of the free radical photoinitiator and the photoacid generator ranges from about 99.8:0.2 to 90:10. In another example, a mass ratio of the monomer(s) or cross-linkable copolymer(s) to the direct photoacid generator or the combination of the free radical photoinitiator and the photoacid generator ranges from about 98:2 to 95:5. In still another example, a mass ratio of the monomer(s) or cross-linkable copolymer(s) to the direct photoacid generator or the combination of the free radical photoinitiator and the photoacid generator ranges from about 96:4 to 99:1. When lower amounts of the direct photoacid generator or the combination of the free radical photoinitiator and the photoacid generator are included, the UV cure time may have to be increased to allow for complete reaction to form the sacrificial resin layer 26.

Any of the solvents described herein for the epoxy siloxane resin composition may be used as the solvent in the organic epoxy composition in any of the provided amounts. When included in the organic epoxy composition, the surface additive may be selected from any of the examples provided for the epoxy siloxane resin composition and may be used in any of the provided amounts.

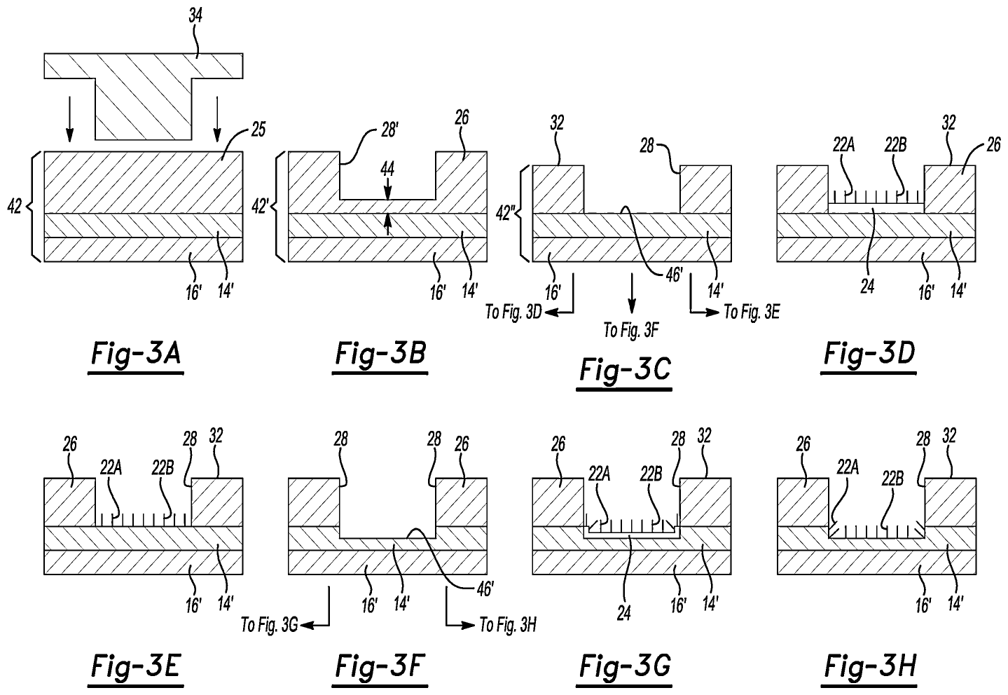

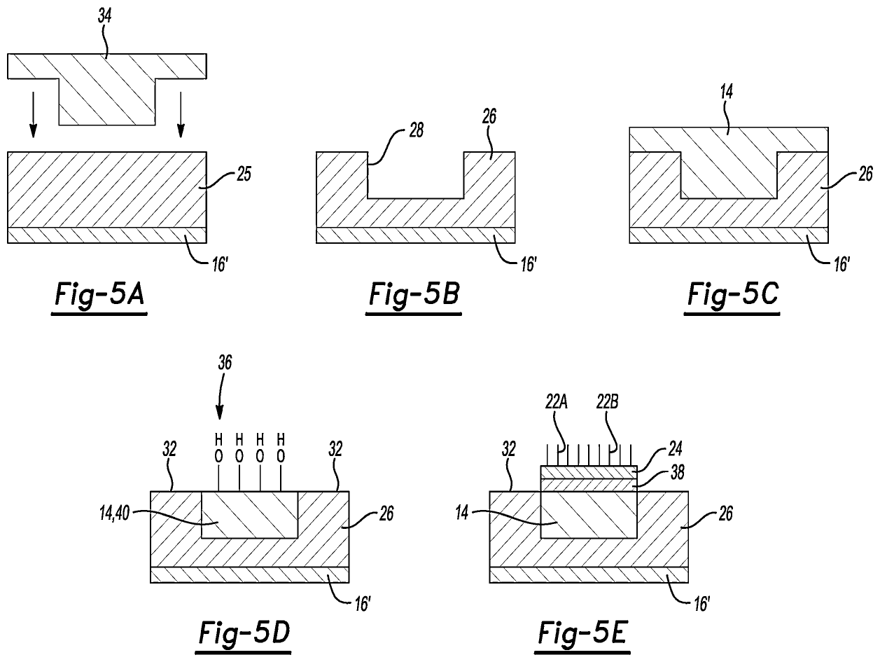

As will be described in reference to some of the examples of the method disclosed herein, the acrylate, fluorinated, or organic epoxy resin composition is photocured to form the sacrificial resin layer 26. The acrylate, fluorinated, or organic epoxy resin compositions are generally depicted at reference numeral 25 in FIG. 2A, FIG. 3A, and FIG. 5A.

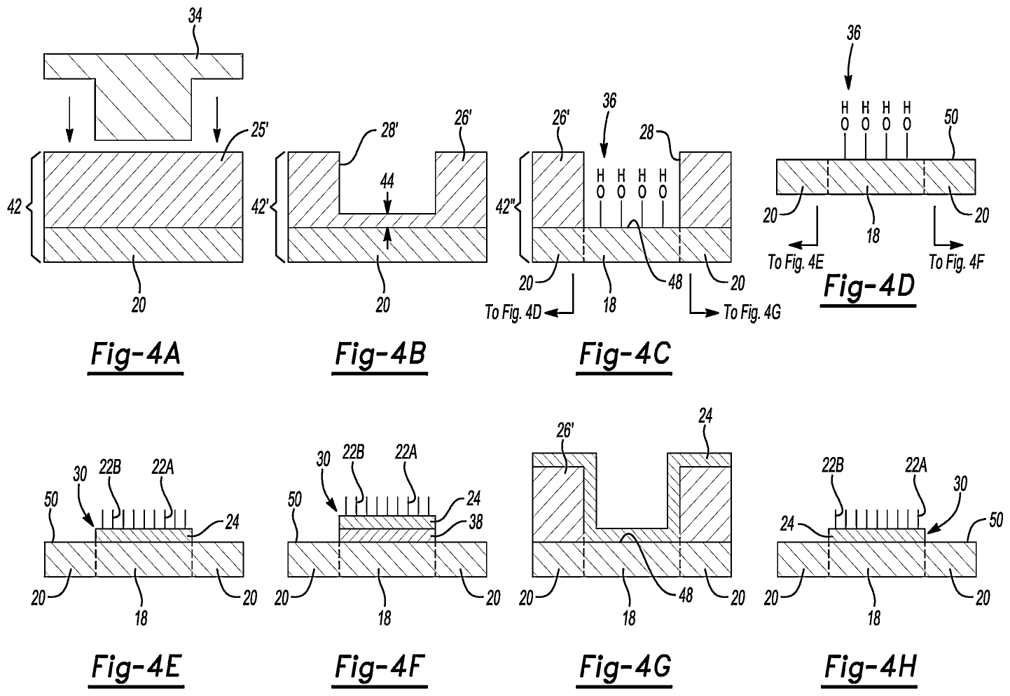

Another example of a sacrificial resin layer 26′ is used in examples of the method (see FIG. 4A through FIG. 4H), but the layer 26′ does not end up in the final flow cell architecture. This sacrificial resin layer 26′ is formed from a sacrificial resin composition including from greater than 0 mass % to 50 mass %, based on a total monomer content of the sacrificial resin composition, of 3,4-epoxycyclohexylmethyl 3,4-epoxycyclohexanecarboxylate:

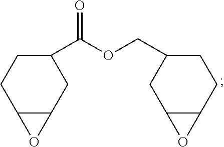 [SMILES: O=C(OCC1CCC2OC2C1)C1CCC2OC2C1]

from 50 mass % to less than 100 mass % based on the total monomer content of the sacrificial resin composition, of trimethylolpropane triglycidyl ether; a photoacid generator; an optional surface additive; and a solvent.

Any of the photoacid generators described herein for the epoxy siloxane resin composition may be used in the sacrificial resin composition. In an example of the sacrificial resin composition, a mass ratio of the monomers to the photoacid generator ranges from about 99.8:0.2 to 90:10 or any of the sub-ranges provided herein. When lower amounts of the photoacid generator are included, the UV cure time may have to be increased to allow for complete reaction to form the sacrificial resin layer 26′.

Any of the solvents described herein for the epoxy siloxane resin composition may be used as the solvent in the sacrificial resin composition in any of the provided amounts. When included in the organic epoxy composition, the surface additive may be selected from any of the examples provided for the epoxy siloxane resin composition and may be used in any of the provided amounts.

As will be described in reference to some of the examples of the method disclosed herein, the sacrificial resin composition is photocured to form the sacrificial resin layer 26′. The sacrificial resin composition is generally depicted at reference numeral 25′ in FIG. 4A.

The sacrificial resin layer 26′ is used to generate the architecture shown in FIG. 1D, which also includes the hydrophobic layer 20. The hydrophobic layer 20 is selected from the group consisting of a fluoropolymer and a hexamethyl disilazane. Any of the fluorinated resin compositions disclosed herein may be used for the hydrophobic layer 20. In other examples, the fluoropolymer may be an amorphous (non-crystalline) fluoropolymer (e.g., CYTOP® from Bellex), a crystalline fluoropolymer, or a fluoropolymer having both amorphous and crystalline domains.

As shown in FIG. 1D, the hydrophobic layer 20 also includes wettable portions 18. These portions have been exposed to air or O₂ plasma, which introduces hydrophilic functional groups (e.g., —OH groups) to the portions 18 rendering them wettable, i.e., capable of covalently attaching to the polymeric hydrogel 24 or to primers 22A, 22B. The wettable portion(s) 18 are surrounded by hydrophobic interstitial regions 50.

In any of the example architectures including the hydrophobic layer 20, the hydrophobic layer 20 may be supported by any example of the base support 16′. In this example, the base support 16′ is used as an underlying support structure for the flow cell substrate.

Each of the architectures shown in FIG. 1B through FIG. 1E includes the polymeric hydrogel 24 and the primers 22A, 22B attached to the polymeric hydrogel 24. It is to be understood that the example shown in FIG. 1D may alternatively include the primers 22A, 22B directly attached to the modified portions 18.

The polymeric hydrogel 24 may be any gel material that can swell when liquid is taken up and can contract when liquid is removed, e.g., by drying. In an example, the polymeric hydrogel 24 includes an acrylamide copolymer. Some examples of the acrylamide copolymer are represented by the following structure (I):

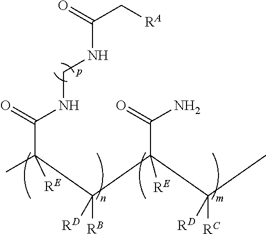

wherein:
R^{A} is selected from the group consisting of azido, optionally substituted amino, optionally substituted alkene, optionally substituted alkenyl, optionally substituted alkyne, halogen, optionally substituted hydrazone, optionally substituted hydrazine, carboxyl, hydroxy, optionally substituted tetrazole, optionally substituted tetrazine, nitrile oxide, nitrone, sulfate, and thiol;
R^{B} is H or optionally substituted alkyl;
R^{C}, R^{D}, and R^{E} are each independently selected from the group consisting of H and optionally substituted alkyl;
each of the —(CH₂)ₚ— can be optionally substituted;
p is an integer in the range of 1 to 50;
n is an integer in the range of 1 to 50,000; and
m is an integer in the range of 1 to 100,000.

One specific example of the acrylamide copolymer represented by structure (I) is poly(N-(5-azidoacetamidylpentyl)acrylamide-co-acrylamide, PAZAM.

One of ordinary skill in the art will recognize that the arrangement of the recurring “n” and “m” features in structure (I) are representative, and the monomeric subunits may be present in any order in the polymer structure (e.g., random, block, patterned, or a combination thereof).

The molecular weight of the acrylamide copolymer may range from about 5 kDa to about 1500 kDa or from about 10 kDa to about 1000 kDa, or may be, in a specific example, about 312 kDa.

In some examples, the acrylamide copolymer is a linear polymer. In some other examples, the acrylamide copolymer is a lightly cross-linked polymer.

In other examples, the gel material may be a variation of structure (I). In one example, the acrylamide unit may be replaced with N,N-dimethylacrylamide

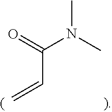

In this example, the acrylamide unit in structure (I) may be replaced with,

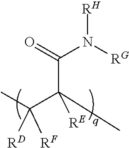

where R^{D}, R^{E}, and R^{F} are each H or a C1-C6 alkyl, and R^{G} and RH are each a C1-C6 alkyl (instead of H as is the case with the acrylamide). In this example, q may be an integer in the range of 1 to 100,000. In another example, the N,N-dimethylacrylamide may be used in addition to the acrylamide unit. In this example, structure (I) may include

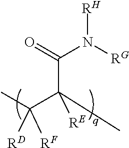

in addition to the recurring “n” and “m” features, where RD, RE, and RF are each H or a C1-C6 alkyl, and R^{G} and R^{H} are each a C1-C6 alkyl. In this example, q may be an integer in the range of 1 to 100,000.

As another example of the polymeric hydrogel 24, the recurring “n” feature in structure (I) may be replaced with a monomer including a heterocyclic azido group having structure (II):

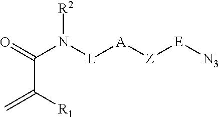

wherein R¹ is H or a C1-C6 alkyl; R₂ is H or a C1-C6 alkyl; L is a linker including a linear chain with 2 to 20 atoms selected from the group consisting of carbon, oxygen, and nitrogen and 10 optional substituents on the carbon and any nitrogen atoms in the chain; E is a linear chain including 1 to 4 atoms selected from the group consisting of carbon, oxygen and nitrogen, and optional substituents on the carbon and any nitrogen atoms in the chain; A is an N substituted amide with an H or a C1-C4 alkyl attached to the N; and Z is a nitrogen containing heterocycle. Examples of Z include 5 to 10 carbon-containing ring members present as a single cyclic structure or a fused structure. Some specific examples of Z include pyrrolidinyl, pyridinyl, or pyrimidinyl. As still another example, the gel material may include a recurring unit of each of structure (III) and (IV):

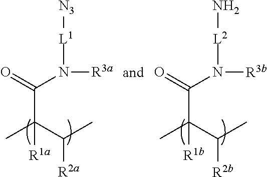

wherein each of R^{1a}, R^{2a}, R^{1b} and R^{2b} is independently selected from hydrogen, an optionally substituted alkyl or optionally substituted phenyl; each of R^{3a} and R^{3b} is independently selected from hydrogen, an optionally substituted alkyl, an optionally substituted phenyl, or an optionally substituted C7-C14 aralkyl; and each L¹ and L² is independently selected from an optionally substituted alkylene linker or an optionally substituted heteroalkylene linker.

In still another example, the acrylamide copolymer is formed using nitroxide mediated polymerization, and thus at least some of the copolymer chains have an alkoxyamine end group. In the copolymer chain, the term “alkoxyamine end group” refers to the dormant species —ONR₁R₂, where each of R₁ and R₂ may be the same or different, and may independently be a linear or branched alkyl, or a ring structure, and where the oxygen atom is attached to the rest of the copolymer chain. In some examples, the alkoxyamine may also be introduced into some of the recurring acrylamide monomers, e.g., at position R^{A} in structure (I). As such, in one example, structure (I) includes an alkoxyamine end group; and in another example, structure (I) includes an alkoxyamine end group and alkoxyamine groups in at least some of the side chains.

A variety of polymer architectures containing acrylic monomers (e.g., acrylamides, acrylates etc.) may be utilized in the examples disclosed herein, such as branched polymers, including dendrimers (e.g., multi-arm or star polymers), star-shaped or star-block polymers, and the like. For example, the monomers (e.g., acrylamide, etc.) may be incorporated, either randomly or in block, into the branches (arms) of a dendrimer.

In some examples, as shown in FIG. 1B and FIG. 1C, the polymeric hydrogel 24 is introduced into depressions 28. The depressions 28 may be defined in the resin(s) 26, 14 and/or 14′ or in the resin 26 and the base support 16. In other examples, as shown in FIG. 1D and FIG. 1E, the polymeric hydrogel 24 is formed as a pad 30 on the surface of the modified portion 18 or the resin 14.

Many different layouts of the depressions 28 and pads 30 may be envisaged, including regular, repeating, and non-regular patterns. In an example, the depressions 28 or pads 30 disposed in a hexagonal grid for close packing and improved density. Other layouts may include, for example, rectangular layouts, triangular layouts, and so forth. In some examples, the layout or pattern can be an x-y format in rows and columns. In some other examples, the layout or pattern can be a repeating arrangement of the depressions 28 or pads 30 and interstitial regions 32 or 50. In still other examples, the layout or pattern can be a random arrangement of the depressions 28 or pads 30 and the interstitial regions 32 or 50.

The layout or pattern may be characterized with respect to the density (number) of the depressions 28 or pads 30 in a defined area. For example, the depressions 28 or pads 30 may be present at a density of approximately 2 million per mm². The density may be tuned to different densities including, for example, a density of about 100 per mm², about 1,000 per mm², about 0.1 million per mm², about 1 million per mm², about 2 million per mm², about 5 million per mm², about 10 million per mm², about 50 million per mm², or more, or less. It is to be further understood that the density can be between one of the lower values and one of the upper values selected from the ranges above, or that other densities (outside of the given ranges) may be used. As examples, a high density array may be characterized as having depressions 28 or pads 30 separated by less than about 100 nm, a medium density array may be characterized as having the depressions 20 separated by about 400 nm to about 1 μm, and a low density array may be characterized as having the depressions 28 or pads 30 separated by greater than about 1 μm.

The layout or pattern of the depressions 28 or pads 30 may also or alternatively be characterized in terms of the average pitch, or the spacing from the center of one depression 28 or pad 30 to the center of an adjacent depression 28 or pad 30 (center-to-center spacing) or from the right edge of one depression 28 or pad 30 to the left edge of an adjacent depression 28 or pad 30 (edge-to-edge spacing). The pattern can be regular, such that the coefficient of variation around the average pitch is small, or the pattern can be non-regular in which case the coefficient of variation can be relatively large. In either case, the average pitch can be, for example, about 50 nm, about 0.1 μm, about 0.5 μm, about 1 μm, about 5 μm, about 10 μm, about 100 μm, or more or less. The average pitch for a particular pattern can be between one of the lower values and one of the upper values selected from the ranges above. In an example, the depressions 28 or pads 30 have a pitch (center-to-center spacing) of about 1.5 μm. While example average pitch values have been provided, it is to be understood that other average pitch values may be used.

The size of each depression 28 may be characterized by its volume, opening area, depth, and/or diameter or length and width. For example, the volume can range from about 1×10⁻³ μm³ to about 100 μm³, e.g., about 1×10⁻² μm³, about 0.1 μm³, about 1 μm³, about 10 μm³, or more, or less. For another example, the opening area can range from about 1×10⁻³ μm² to about 100 μm², e.g., about 1×10⁻² μm², about 0.1 μm², about 1 μm², at least about 10 μm², or more, or less. For still another example, the depth can range from about 0.1 μm to about 100 μm, e.g., about 0.5 μm, about 1 μm, about 10 μm, or more, or less. For yet another example, the diameter or length and width can range from about 0.1 μm to about 100 μm, e.g., about 0.5 μm, about 1 μm, about 10 μm, or more, or less.

The size of each pad 30 may be characterized by its top surface area, height, and/or diameter or length and width. In an example, the top surface area can range from about 1×10⁻³ μm² to about 100 μm², e.g., about 1×10⁻² μm², about 0.1 μm², about 1 μm², at least about 10 μm², or more, or less. For still another example, the height can range from about 0.1 μm to about 100 μm, e.g., about 0.5 μm, about 1 μm, about 10 μm, or more, or less. For yet another example, the diameter or length and width can range from about 0.1 μm to about 100 μm, e.g., about 0.5 μm, about 1 μm, about 10 μm, or more, or less.

Each example of the flow cell architecture also includes primers 22A, 22B. The primers 22A, 22B make up a primer set that is used in sequential paired end sequencing. As examples, the primer set may include P5 and P7 primers, P15 and P7 primers, or any combination of the PA primers, the PB primers, the PC primers, and the PD primers set forth herein. As examples, the primer set may include any two PA, PB, PC, and PD primers, or any combination of one PA primers and one PB, PC, or primer PD, or any combination of one PB primers and one PC or primer PD, or any combination of one PC primer and one primer PD.

Examples of P5 and P7 primers are used on the surface of commercial flow cells sold by Illumina Inc. for sequencing, for example, on HISEQ™, HISEQX™, MISEQ™, MISEQDX™, MINISEQ™, NEXTSEQ™, NEXTSEQDX™, NOVASEQ™, ISEQ™, GENOME ANALYZER™, and other instrument platforms. The P5 primer is:

P5: 5′ → 3′
(SEQ. ID. NO. 1)
AATGATACGGCGACCACCGAGAUCTACAC
The P7 primer may be any of the following:
P7 #1: 5′ → 3′
(SEQ. ID. NO. 2)
CAAGCAGAAGACGGCATACGAnAT
P7 #2: 5′ → 3′
(SEQ. ID. NO. 3)
CAAGCAGAAGACGGCATACnAGAT
P7 #3: 5′ → 3′
(SEQ. ID. NO. 4)
CAAGCAGAAGACGGCATACnAnAT

where “n” is 8-oxoguanine in each of these sequences.

The P15 primer is:

P15: 5′ → 3′
(SEQ. ID. NO. 5)
AATGATACGGCGACCACCGAGAnCTACAC

where “n” is allyl modified T.

The other primers (PA-PD) mentioned above include:

PA 5′ → 3′
(SEQ. ID. NO. 6)
GCTGGCACGTCCGAACGCTTCGTTAATCCGTTGAG
CPA (PA′) 5′ → 3′
(SEQ. ID. NO. 7)
CTCAACGGATTAACGAAGCGTTCGGACGTGCCAGC
PB 5′ → 3′
(SEQ. ID. NO. 8)
CGTCGTCTGCCATGGCGCTTCGGTGGATATGAACT
CPB (PB′) 5′ → 3′
(SEQ. ID. NO. 9)
AGTTCATATCCACCGAAGCGCCATGGCAGACGACG
PC 5′ → 3′
(SEQ. ID. NO. 10)
ACGGCCGCTAATATCAACGCGTCGAATCCGCAACT
cPC (PC′) 5′ → 3′
(SEQ. ID. NO. 11)
AGTTGCGGATTCGACGCGTTGATATTAGCGGCCGT
PD 5′ → 3′
(SEQ. ID. NO. 12)
GCCGCGTTACGTTAGCCGGACTATTCGATGCAGC
CPD (PD′) 5′ → 3′
(SEQ. ID. NO. 13)
GCTGCATCGAATAGTCCGGCTAACGTAACGCGGC.

While not shown in the example sequences for PA-PD, it is to be understood that any of these primers may include a cleavage site, such as uracil, 8-oxoguanine, allyl-T, etc. at any point in the strand.

Each of the primers 22A, 22B disclosed herein may also include a polyT sequence at the 5′ end of the primer sequence. In some examples, the polyT region includes from 2 T bases to 20 T bases. As specific examples, the polyT region may include 3, 4, 5, 6, 7, or 10 T bases.

The 5′ end of each primer 22A, 22B may also include a linker. Any linker that includes a terminal alkyne group or another suitable terminal functional group that can attach to the functional groups of an underlying layer may be used. As examples, the linker of the primers 22A, 22B may be capable of attaching to wettable surface functional groups of the polymeric hydrogel 24 (e.g., in the depression 28 or as a pad 30), or functional groups of the modified portion 18, or functional groups of the resin layer 14 or 14′, or functional groups of the base support 16, 16′. In one example, the primers 22A, 22B are terminated with hexynyl.

Methods for Making Flow Cells

Different examples of the methods utilizing the orthogonal resins or the orthogonal resin and base support are shown in the series of figures set forth in FIG. 2A through FIG. 2G, FIG. 3A through FIG. 3H, FIG. 4A through FIG. 4H, and FIG. 5A through FIG. 5E. In particular, the methods shown in FIG. 2A through FIG. 2G and FIG. 3A through FIG. 3H may be used to generate the architecture shown in FIG. 1B or FIG. 1C; the methods shown in FIG. 4A through FIG. 4H may be used to generate the architecture shown in FIG. 1D; and the method shown in FIG. 5A through FIG. 5E may be used to generate the architecture shown in FIG. 1E.

Referring now to FIG. 2A through FIG. 2G, two examples of the method are depicted. One example is shown in FIG. 2A through FIG. 2E and the other example is shown in FIG. 2A through FIG. 2C, FIG. 2F and FIG. 2G. These methods generally include defining an initial depression 28′ in a first resin layer (which, in this example, is the sacrificial resin layer 26) of a multi-layer stack (42, 42′, 42″) including the first resin layer 26 over a second resin layer (which, in this example is the resin layer 14) or a base support 16, the first resin layer 26 being resistant to silanization in an organic solvent, the second resin layer 14 or the base support 16 being reactive toward silanization in the organic solvent, and the first resin layer 26 and the second resin layer 14 or the base support 16 being orthogonally etchable; anisotropically etching, using air or O₂ plasma, through a remaining portion 44 of the first resin layer 26 at the initial depression 28′ to expose a surface of the second resin layer 14 or the base support 16 and form a depression 28; and exposing the multi-layer stack 42′ to a silane in the organic solvent, thereby selectively silanizing the surface of the second resin layer 14 or the base support 16 at the depression 28.

In some examples of the methods shown in FIG. 2A through FIG. 2G, the multi-layer stack 42 includes the first (sacrificial) resin layer 26 over the second resin layer 14; the first resin layer 26 is selected from the group consisting of the photocured acrylate resin composition described herein, the photocured fluorinated resin composition described herein, and the photocured organic epoxy resin composition described herein; and the second resin layer 14 is the photocured siloxane-based resin composition described herein.

In other examples of the methods shown in FIG. 2A through FIG. 2G, the multi-layer stack 42 includes the first (sacrificial) resin layer 26 over the base support 16; the first resin layer 26 is selected from the group consisting of the photocured acrylate resin composition described herein, the photocured fluorinated resin composition described herein, and the photocured organic epoxy resin composition described herein; and the base support 16 is glass.

It is to be understood that when the resin layer 14 is used, its precursor composition, i.e., the epoxy siloxane resin composition, has been deposited and cured to form the resin layer 14. To form the resin layer 14, the epoxy siloxane resin composition may be deposited on a base support 16′ (not shown in FIG. 2A) or on a fabrication bed from which the resin layer 14 can be released. The epoxy siloxane resin composition may be deposited using any suitable application technique, which may be manual or automated. As examples, the application of the epoxy siloxane resin composition may be performed using vapor deposition techniques, coating techniques, or the like. Some specific examples include chemical vapor deposition (CVD), spray coating (e.g., ultrasonic spray coating), spin coating, dunk or dip coating, doctor blade coating, puddle dispensing, aerosol printing, screen printing, microcontact printing, inkjet printing, or the like. In one example, spin coating is used.

The technique used to apply the epoxy siloxane resin composition may cause at least some of the solvent to evaporate. After the epoxy siloxane resin composition is applied to the base support 16′ or the fabrication bed, it may be soft baked to remove excess solvent. The soft bake may take place at a lower temperature than is used for curing (e.g., ranging from about 50° C. to about 150° C.) and for a time ranging from greater than 0 seconds to about 3 minutes. In an example, the soft bake time ranges from about 30 seconds to about 2.5 minutes.

Curing may be accomplished by exposing the applied epoxy siloxane resin composition to incident light at an energy dose ranging from about 0.5 J to about 20 J for 30 seconds or less. The incident light may be actinic radiation, such as ultraviolet (UV) radiation. In one example, the majority of the UV radiation emitted may have a wavelength of about 365 nm.

In some examples disclosed herein, the energy exposure promotes decomposition of the direct photoacid generator into an acid that initiates polymerization and/or cross-linking of the epoxy siloxane resin composition. In some instances, the incident light exposure time may be 30 seconds or less. In other instances, the incident light exposure time may be 20 seconds or less. In still other instances, the incident light exposure time may be about 5 seconds.

In other examples disclosed herein, the energy exposure causes the photoinitiator to generate free radicals, which promote decomposition of the photoacid generator into an acid that initiates polymerization and/or cross-linking of the epoxy siloxane resin composition. With the effective extent of curing brought on by this mechanism, the incident light exposure time may be 30 seconds or less. In some instances, the incident light exposure time may be 20 seconds or less. In still other instances, the incident light exposure time may be about 5 seconds.

The curing process may include a single UV exposure stage. After curing, the resin layer 14 is formed.

In some instances, it may be desirable to perform a post-curing bake process. If performed, the post-curing bake may take place at a temperature ranging from about 150° C. to about 250° C. for a time ranging from about 1 minute to about 2 minutes.

The exact chemical make-up of the resin layer 14 depends upon the monomer(s) or cross-linkable copolymer(s) and the initiating system (e.g., the direct photoacid generator or the combination of the photoinitiator and the photoacid generator) used in the epoxy siloxane resin composition.

It is to be understood that when the base support 16 is used, it is selected so that it is capable of supporting the surface chemistry (e.g., primers 22A, 22B, or primers 22A, 22B and polymer hydrogel 24).

In FIG. 2A, the acrylate, fluorinated, or organic epoxy resin composition 25 is deposited on the resin layer 14 or the base support 16. Any example of the acrylate, fluorinated, or organic epoxy resin composition 25 disclosed herein may be used. The acrylate, fluorinated, or organic epoxy resin composition 25 is deposited on the resin layer 14 or the base support 16 using any suitable technique. The acrylate, fluorinated, or organic epoxy resin composition 25 may then be soft baked as described herein.

The method then includes imprinting the acrylate, fluorinated, or organic epoxy resin composition 25 with a working stamp 34 having a negative replica of the initial depression 28′; and photocuring the acrylate, fluorinated, or organic epoxy resin composition 25 while the working stamp 34 is in place, thereby forming the photocured acrylate, fluorinated, or organic epoxy resin composition (each of which is an example of the sacrificial resin layer 26) having the initial depression 28′ defined therein.

The acrylate, fluorinated, or organic epoxy resin composition 25 may be patterned using any suitable patterning technique. In the example shown in FIG. 2A, nanoimprint lithography is used to pattern the acrylate, fluorinated, or organic epoxy resin composition 25. A nanoimprint lithography mold or working stamp 34 is pressed against the acrylate, fluorinated, or organic epoxy resin composition 25 to create an imprint in the acrylate, fluorinated, or organic epoxy resin composition 25. In other words, the acrylate, fluorinated, or organic epoxy resin composition 25 is indented or perforated by the nanofeatures the working stamp 34. The acrylate, fluorinated, or organic epoxy resin composition 25 may be then be cured with the working stamp 34 in place. The curing process may be performed as described herein, except that the incident light exposure time may be shorter, e.g., 10 seconds or less (5 seconds, 2 seconds, etc.). After curing, the working stamp 34 is released. Patterning generates topographic features that are defined in the photocured sacrificial resin layer 26, as shown in FIG. 2B. In this example, the features that are formed include the initial depressions 28′, which do not extend through to the underlying resin layer 14 or base support 16.

The patterned multi-layer stack 42′ (shown in FIG. 2B) is exposed to anisotropic etching using air or 100% O₂ plasma. The first/sacrificial resin layer 26 is susceptible to the air or O₂ plasma. As such, the entire exposed surface of the first/sacrificial resin layer 26 is etched, which removes the portion 44 remaining at the initial depression 28′ and also removes some of the convex portions that are adjacent to the initial depression 28′. As shown in FIG. 2C, etching i) removes the portion 44, which creates the depression 28; and ii) reduces the thickness of the convex portions by the thickness of the portion 44, which creates the interstitial regions 32.

The underlying resin layer 14 or base support 16 is not susceptible to the air or O₂ plasma, as it is orthogonally etchable to the first/sacrificial resin layer 26. Thus, the surface of the resin layer 14 or base support 16 acts as an etch stop when the portion 44 of the first/sacrificial resin layer 26 is removed. The air or O₂ plasma activates the exposed surface 46 of the resin layer 14 or base support 16 by generating reactive groups 36 (e.g., —OH groups), as shown in FIG. 2C.

One example of the method continues from FIG. 2C to FIG. 2D.

The reactive groups 36 at the surface 46 of the resin layer 14 or base support 16 and the interstitial regions 32 of the first/sacrificial resin layer 26 exhibit orthogonal silane solution reactivity. As such, the patterned multi-layer stack 42″ shown in FIG. 2C can be exposed to a silane in an organic solvent, which selectively silanizes the surface 46 of the resin layer 14 or the base support 16 at the depression 28. In one example, the silane is norbornene silane and the organic solvent is acetonitrile. The silane solution may be allowed to react at the surface 46 at a temperature ranging from about 15° C. to about 30° C. for a time ranging from about 15 minutes to about 4 hours. The surface of the multi-layer stack 42″ may then be rinsed. After silane solution exposure, and as shown in FIG. 2D, the surface 46 of the resin layer 14 or the base support 16 at the depression 28 is silanized (referred to herein as the silanized surface or layer 38), and the interstitial regions 32 of the first/sacrificial resin layer 26 remain unaffected by the silane.

Referring now to FIG. 2E, the method further includes applying the polymeric hydrogel 24 to the silanized surface 38 of the resin layer 14 or the base support 16 at the depression 28. In this example, the polymeric hydrogel 24 may be any of the gel materials described herein and may be applied using any suitable deposition technique and cured. In an example, polymeric hydrogel 24 curing may take place at a temperature ranging from room temperature (e.g., about 25° C.) to about 95° C. for a time ranging from about 1 millisecond to about several days. As shown in FIG. 2E, the polymeric hydrogel 24 is applied over the silanized surface 38 in the depression 28, but is not applied over the interstitial regions 32 of the first/sacrificial resin layer 26. The polymeric hydrogel 24 covalently attaches to the silanized surface 38, but does not covalently attach to the interstitial regions 32. Because of the different interactions at the surface 38 and at the interstitial regions 32, the polymeric hydrogel 24 remains over the surface 38, and can be easily removed (e.g., via sonication, washing, wiping, etc.) from the interstitial regions 32. Thus, the interstitial regions 32 are not exposed to polishing.

As shown in FIG. 2E, the primers 22A, 22B are grafted to the polymeric hydrogel 24. In some examples, the primers 22A, 22B may be pre-grafted to the polymeric hydrogel 24. In these examples, additional primer grafting is not performed.

In other examples, the primers 22A, 22B are not pre-grafted to the polymeric hydrogel 24. In these examples, the primers 22A, 22B may be grafted after the polymeric hydrogel 24 is applied. As examples, grafting may be accomplished by flow through deposition (e.g., using a temporarily bound lid), dunk coating, spray coating, puddle dispensing, or by another suitable method. Each of these example techniques may utilize a primer solution or mixture, which may include the primer(s) 22A, 22B, water, a buffer, and a catalyst. With any of the grafting methods, the primers 22A, 22B attach to the reactive groups of the polymeric hydrogel 24 and do not react with the interstitial regions 32.

While a single depression 28 with surface chemistry introduced therein is shown in FIG. 2E, it is to be understood that the method described in reference to FIG. 2A through FIG. 2E may be performed to generate an array of depressions 28 (each having the polymeric hydrogel 24 and primers 22A, 22B therein) separated by interstitial regions 32 across the surface of the resin layer 14 or base support 16.

Referring back to FIG. 2C, another example of the method continues at FIG. 2F. In this example of the method, prior to exposing the multi-layer stack 42″ to the silane, the method further includes anisotropically etching, using fluorinated plasma, the resin layer 14 or the base support 16 at the depression 28 to extend the depression 28 a predetermined distance into the second resin layer 14 or the base support 16. Examples of a suitable fluorinated plasma include CF₄ plasma, SF₆ plasma, CHF₃ plasma, or C₄F₈ plasma. This etching process may be timed so that a desired portion of the resin layer 14 or the base support 16 is removed from the depression 28. The depression 28 with its depth extending partially into the thickness of the resin layer 14 or the base support 16 is shown in FIG. 2F.

The reactive groups 36 at the surface 46 of the resin layer 14 or base support 16 generated during etching of the sacrificial resin layer 26 remain active during etching of the resin layer 14 or base support 16. As such, the surface 46 and the interstitial regions 32 of the first/sacrificial resin layer 26 still exhibit orthogonal silane solution reactivity. As described in reference to FIG. 2D, the patterned multi-layer stack 42″ shown in FIG. 2C can be exposed to a silane in an organic solvent, which selectively silanizes the surface 46 of the resin layer 14 or the base support 16 at the depression 28. In one example, the silane is norbornene silane and the organic solvent is acetonitrile. The silane solution may be allowed to react at the surface 46 at a temperature ranging from about 15° C. to about 30° C. for a time ranging from about 15 minutes to about 4 hours. The silanized surface 38 is shown in FIG. 2G.

Also shown in FIG. 2G are the polymeric hydrogel 24 and the primers 22A, 22B. The polymeric hydrogel 24 may be applied, and the primers 22A, 22B may be grafted as described in reference to FIG. 2E.

While a single depression 28 with surface chemistry introduced therein is shown in FIG. 2G, it is to be understood that the method described in reference to FIG. 2A through FIG. 2C, FIG. 2F and FIG. 2G may be performed to generate an array of depressions 28 (each extending at least partially into the depth of the resin layer 14 or the base support 16 and having the polymeric hydrogel 24 and primers 22A, 22B therein) separated by interstitial regions 32 across the surface of the resin layer 14 or base support 16.

Referring now to FIG. 3A through FIG. 3G, four examples of the method are depicted. One example is shown in FIG. 3A through FIG. 3D; another example is shown in FIG. 3A through FIG. 3C and FIG. 3E; still another example is shown in FIG. 3A through FIG. 3C, FIG. 3F, and FIG. 3G; and yet a further example is shown in FIG. 3A through FIG. 3C, FIG. 3F, and FIG. 3H. These methods generally include defining an initial depression 28′ in a first resin layer 26 of a multi-layer stack 42′ including the first (sacrificial) resin layer 26 over a second resin layer 14′ over a base support 16′, the first resin layer 26 including a first functional group that is non-reactive with sequencing surface chemistry and the second resin layer 14′ including a second functional group that is reactive with the sequencing surface chemistry; anisotropically etching, using air or O₂ plasma, through a remaining portion 44 of the first resin layer 26 at the initial depression 28′ to expose a surface 46′ of the second resin layer 14′ and to form a depression 28, whereby the second functional group remains reactive; and exposing the multi-layer stack 42″ to the surface chemistry, thereby attaching the sequencing surface chemistry to the second functional group.

In these example methods, the resin layer 14′ described herein is used because it is orthogonally anisotropically etchable and orthogonally reactive relative to the sacrificial resin layer 26. In an example, the resin layer 14′ is the photocured thiol-ene resin composition.

Prior to defining the initial depression 28′, the multi-layer stack 42 shown in FIG. 3A may be formed by depositing the thiol-ene resin composition described herein on the base support 16′; photocuring the thiol-ene resin composition, thereby forming the resin layer 14′; and depositing the acrylate, fluorinated, or organic epoxy resin composition 25 on the resin layer 14′. Deposition of the respective compositions may be performed using any of the techniques described herein, and the thiol-ene resin composition may be photocured by exposing the applied thiol-ene resin composition to incident light at an energy dose ranging from about 0.5 J to about 20 J for 30 seconds or less. In this example, the energy exposure causes the initiator to generate free radicals, which promotes polymerization of the monomer(s).

Once the multi-layer stack 42 is formed, the acrylate, fluorinated, or organic epoxy resin composition 25 may be patterned to form the initial depression 28′ (FIG. 3B). In an example, the initial depression 28′ is defined by imprinting the acrylate, fluorinated, or organic epoxy resin composition 25 with a working stamp 34 having a negative replica of the initial depression 28′; and photocuring the acrylate, fluorinated, or organic epoxy resin composition 25 while the working stamp 34 is in place, thereby forming the first (sacrificial) resin layer 26 having the initial depression 28′ defined therein. Nanoimprinting may be performed as described herein in reference to FIG. 2A and FIG. 2B.

The patterned multi-layer stack 42′ (shown in FIG. 3B) is then exposed to anisotropic etching using air or 100% O₂ plasma. The first/sacrificial resin layer 26 is susceptible to the air or O₂ plasma. As such, the entire exposed surface of the first/sacrificial resin layer 26 is etched, which removes the portion 44 remaining at the initial depression 28′ and also removes some of the convex portions that are adjacent to the initial depression 28′. As shown in FIG. 3C, etching i) removes the portion 44, which creates the depression 28; and ii) reduces the thickness of the convex portions by the thickness of the portion 44, which creates the interstitial regions 32.

The underlying resin layer 14′ is not susceptible to the air or O₂ plasma, as it is orthogonally etchable to the first/sacrificial resin layer 26. Thus, the surface of the resin layer 14′ acts as an etch stop when the portion 44 of the first/sacrificial resin layer 26 is removed. The resin layer 14′ includes reactive groups (e.g., reactive —SH groups) which are unaffected by the air or O₂ plasma etching. Thus, the surface 46′ exposed in the depression 28 is ready to receive surface chemistry.

One example of the method continues from FIG. 3C to FIG. 3D, where the polymeric hydrogel 24 and the primers 22A, 22B are introduced into the depression 28; and another example of the method continues from FIG. 3C to FIG. 3E, where the primers 22A, 22B alone are introduced into the depression 28. In either of these examples, the interstitial regions 32 are non-reactive with the sequencing surface chemistry that is to be introduced, and thus, the surface chemistry can be selectively applied within the depression 28.

In the example shown in FIG. 3D, the polymeric hydrogel 24 is applied to the surface 46, and the primers 22A, 22B are grafted thereto. In this particular example, the polymeric hydrogel 24 is selected to include at least some alkene functional groups (e.g., R^{A} in structure I), which can react with the reactive thiol groups at the surface 46′ via a thia-Michael Addition reaction. The polymeric hydrogel 24 may be deposited and cured as described herein. Because of the different functional groups at the surface 46′ and at the interstitial regions 32, the polymeric hydrogel 24 covalently attaches to the surface 46′, and can be easily removed (e.g., via sonication, washing, wiping, etc.) from the interstitial regions 32. Thus, the interstitial regions 32 are not exposed to polishing.

The primers 22A, 22B may then be grafted as described herein, or alternatively, may be pre-grafted to the polymeric hydrogel 24.

In the example shown in FIG. 3E, the primers 22A, 22B include a 5′ terminus, such as an alkene, that can react with the reactive thiol groups at the surface 46′. The primers 22A, 22B may be grafted as described herein. Because of the different functional groups at the surface 46′ and at the interstitial regions 32, the primers 22A, 22B covalently attach to the surface 46′, and can be easily removed (e.g., via sonication, washing, wiping, etc.) from the interstitial regions 32. Thus, the interstitial regions 32 are not exposed to polishing.

While a single depression 28 with surface chemistry introduced therein is shown in each of FIG. 3D and FIG. 3E, it is to be understood that the methods described in reference to FIG. 3A through FIG. 3D and FIG. 3A through FIG. 3C and FIG. 3E may each be performed to generate an array of depressions 28 (each having the respective surface chemistry therein) separated by interstitial regions 32 across the surface of the resin layer 14′.

Referring back to FIG. 3C, another example of the method continues at FIG. 3F. In this example of the method, prior to exposing the patterned multi-layer stack 42″ of FIG. 3C to the desirable sequencing surface chemistry, the method further includes anisotropically etching, using fluorinated plasma, the resin layer 14′ at the depression 28 to extend the depression 28 a predetermined distance into the resin layer 14′. Any of the fluorinated plasmas disclosed herein may be used. This etching process may be timed so that a desired portion of the resin layer 14′ is removed from the depression 28. The depression 28 with its depth extending partially into the thickness of the resin layer 14′ is shown in FIG. 3F.

One example of the method continues from FIG. 3F to FIG. 3G, where the polymeric hydrogel 24 and the primers 22A, 22B are introduced into the depression 28; and another example of the method continues from FIG. 3F to FIG. 3H, where the primers 22A, 22B alone are introduced into the depression 28. In either of these examples, the interstitial regions 32 are non-reactive with the sequencing surface chemistry that is to be introduced, and thus, the surface chemistry can be selectively applied within the depression 28.

In the example shown in FIG. 3G, the polymeric hydrogel 24 is applied to the surface 46, and the primers 22A, 22B are grafted thereto. These processes may be performed as described in reference to FIG. 3D.

In the example shown in FIG. 3E, the primers 22A, 22B include a 5′ terminus, e.g., an alkene, which can react with the reactive thiol groups at the surface 46′. The primers 22A, 22B may be grafted as described herein.

While a single depression 28 with surface chemistry introduced therein is shown in each of FIG. 3G and FIG. 3H, it is to be understood that the methods described in reference to FIG. 3A through FIG. 3C, FIG. 3F, and FIG. 3G or FIG. 3H may each be performed to generate an array of depressions 28 (each having the respective surface chemistry therein) separated by interstitial regions 32 across the surface of the resin layer 14′.

Referring now to FIG. 4A through FIG. 4H, three examples of the method are depicted. One example is shown in FIG. 4A through FIG. 4E; another example is shown in FIG. 4A through FIG. 4D and FIG. 4F; and still another example is shown in FIG. 4A through FIG. 4C, FIG. 4G, and FIG. 4H. These methods generally include defining an initial depression 28′ in a sacrificial resin layer 26′ of a multi-layer stack 42′ including the sacrificial resin layer 26′ over a hydrophobic layer 20, wherein the sacrificial resin layer 26′ is etchable in air or O₂ plasma and is dissolvable in an organic solvent and wherein the hydrophobic layer 20 is insoluble in the organic solvent; anisotropically etching, using air or O₂ plasma, through a remaining portion 44 of the sacrificial resin layer 26′ at the initial depression 28′ to expose a surface 48 of the hydrophobic layer 20 and to form a depression 28; continuing the air or O₂ plasma to introduce hydrophilic (wettable) functional groups 36 to the hydrophobic layer 20 at the depression 28, thereby generating a wettable portion 18; and exposing the multi-layer stack 42″ to the organic solvent, thereby removing the sacrificial resin layer 26′ to expose a hydrophobic interstitial region 50 around the wettable portion 18.

In these example methods, the sacrificial resin layer 26′ described herein is used with any example of the hydrophobic layer 20 described herein.

Prior to defining the initial depression 28′, the multi-layer stack 42 shown in FIG. 4A may be formed by depositing the sacrificial resin composition 25′ on the hydrophobic layer 20. Deposition of the sacrificial resin composition 25′ may be performed using any of the techniques described herein.

Once the multi-layer stack 42 is formed, the sacrificial resin composition 25′ may be patterned to form the initial depression 28′ (FIG. 4B). In an example, the initial depression 28′ is defined by imprinting the sacrificial resin composition 25′ with a working stamp 34 having a negative replica of the initial depression 28′; and photocuring the sacrificial resin composition 25′ while the working stamp 34 is in place, thereby forming the first (sacrificial) resin layer 26′ having the initial depression 28′ defined therein. Nanoimprinting may be performed as described herein in reference to FIG. 2A and FIG. 2B.

The patterned multi-layer stack 42′ (shown in FIG. 4B) is then exposed to anisotropic etching using air or 100% O₂ plasma. The first/sacrificial resin layer 26′ is susceptible to the air or O₂ plasma. As such, the entire exposed surface of the first/sacrificial resin layer 26′ is etched, which removes the portion 44 remaining at the initial depression 28′ and also removes some of the convex portions that are adjacent to the initial depression 28′. As shown in FIG. 4C, etching i) removes the portion 44, which creates the depression 28; and ii) reduces the thickness of the convex portions by the thickness of the portion 44.

The underlying hydrophobic layer 20 is not etched by the air or O₂ plasma, but can be activated by exposure to the air or O₂ plasma. Thus, the air or O₂ plasma may be continued to introduce hydrophilic (wettable) functional groups 36 to the hydrophobic layer 20 at the depression 28. This creates the wettable portion 18. In one example, the hydrophobic layer 20 may be exposed to the air or O₂ plasma for a time ranging from about 20 seconds to about 60 seconds.

One example of the method continues from FIG. 4C to FIG. 4D. In FIG. 4D, the sacrificial resin layer 26′ is removed. Removal may be performed by exposing the multi-layer structure 42″ to the organic solvent that is capable of dissolving the sacrificial resin layer 26′, but not affecting the hydrophobic layer 20 or the wettable portion 18. The exposure of the multi-layer structure 42″ to the organic solvent may take place for a time ranging from about 2 minutes to about 30 minutes. In one example, the organic solvent is dimethylsulfoxide; and exposing the multi-layer stack 42″ to the organic solvent involves soaking the multi-layer stack 42″ in the dimethylsulfoxide (DMSO) with sonication. This process exposes the hydrophobic interstitial regions 50 that surround the wettable portion 18.

One example of the method continues from FIG. 4D to FIG. 4E, where the polymeric hydrogel 24 and the primers 22A, 22B are introduced to the wettable portion 18; and another example of the method continues from FIG. 4D to FIG. 4F, where the wettable portion 18 is silanized before the polymeric hydrogel 24 and the primers 22A, 22B are introduced thereto.

In the example shown in FIG. 4E, the polymeric hydrogel 24 is applied to the wettable portion 18, and the primers 22A, 22B are grafted thereto. In this particular example, the polymeric hydrogel 24 is selected to include at least some functional groups (e.g., R^{A} in structure I) that can react with the hydrophilic (wettable) reactive groups 36 at the surface 48 of the wettable portion 18. The polymeric hydrogel 24 may be deposited and cured as described herein. Because of the different functional groups at the surface 48 and at the hydrophobic interstitial regions 50, the polymeric hydrogel 24 covalently attaches to the surface 48, and can be easily removed (e.g., via sonication, washing, wiping, etc.) from the hydrophobic interstitial regions 50. This forms pads 30 of the polymeric hydrogel 24.

The primers 22A, 22B may then be grafted to the pads 30 using any of the techniques described herein, or alternatively, may be pre-grafted to the polymeric hydrogel 24.

In other examples, the polymeric hydrogel 24 may not include functional groups (e.g., R^{A} in structure I) that can react with the hydrophilic (wettable) reactive groups 36 at the surface 48 of the wettable portion 18. In these instances, the wettable portion 18 may be silanized before the polymeric hydrogel 24 is applied. Silanization may be performed as described herein in reference to FIG. 2D. The hydrophobic interstitial regions 50 are not susceptible to silanization, and thus the wettable portions 18 are selectively silanized, as depicted at layer 38 in FIG. 4F.

In the example shown in FIG. 4F, the polymeric hydrogel 24 is then applied to the silanized layer 38 attached to the wettable portion 18, and the primers 22A, 22B are grafted to the polymeric hydrogel 24. The polymeric hydrogel 24 may be deposited and cured as described herein. Because of the different functional groups at the silanized layer 38 and at the hydrophobic interstitial regions 50, the polymeric hydrogel 24 covalently attaches to the silanized layer 38, and can be easily removed (e.g., via sonication, washing, wiping, etc.) from the hydrophobic interstitial regions 50. This forms pads 30 including the silanized layer 38 and the polymeric hydrogel 24.

The primers 22A, 22B may then be grafted to the pads 30 using any of the techniques described herein, or alternatively, may be pre-grafted to the polymeric hydrogel 24.

While a single pad 30 with primers 22A, 22B attached thereto is shown in each of FIG. 4E and FIG. 4F, it is to be understood that the methods described in reference to FIG. 4A through FIG. 4E and FIG. 4A through FIG. 4D and FIG. 4F may each be performed to generate an array of pads 30 (each having the primers 22A, 22B attached thereof) separated by hydrophobic interstitial regions 50 across the hydrophobic layer 20.

Referring back to FIG. 4C, another example of the method continues at FIG. 4G and FIG. 4H. In this example of the method, the sacrificial resin layer 26′ is not removed before polymeric hydrogel 24 application. As such, in this example, the method includes applying the polymeric hydrogel 24 to the wettable portion 18 and the sacrificial resin layer 26′ before the sacrificial resin layer 26′ is removed. In this particular example, the polymeric hydrogel 24 may be selected to include at least some functional groups (e.g., R^{A} in structure I) that can react with the hydrophilic (wettable) reactive groups 36 at the surface 48 of the wettable portion 18. Alternatively, while not shown in FIG. 4G and FIG. 4H, it is to be understood that the wettable portion 18 may be silanized prior to polymeric hydrogel 24 application when the polymeric hydrogel 24 does not include functional groups (e.g., R^{A} in structure I) that can react with the hydrophilic (wettable) reactive groups 36 at the surface 48 of the wettable portion 18. Silanization may be performed as described herein in reference to FIG. 2D. Whether silanization takes place or not, the polymeric hydrogel 24 may be deposited and cured as described herein.

As shown in FIG. 4G, the polymeric hydrogel 24 deposits over the sacrificial resin layer 26′. This example method then includes removing the sacrificial resin layer 26′. Removal of the sacrificial resin layer 26′ may be performed using the organic solvent, as described in reference to FIG. 4D. This process removes i) at least 99% of the sacrificial resin layer 26′ and ii) the polymeric hydrogel 24 positioned thereon. The polymeric hydrogel 24 is covalently attached at the wettable portion 18 (either directly or through the silanized layer 38), and thus is not affected by the removal process. This forms a pad 30 at each wettable portion 18.

In this example method, the primers 22A, 22B may be grafted to the polymeric hydrogel 24 after it is applied as shown in FIG. 4G or in FIG. 4H, or alternatively, may be pre-grafted to the polymeric hydrogel 24 before it is applied.

While a single pad 30 with primers 22A, 22B attached thereto is shown in each of FIG. 4H, it is to be understood that the methods described in reference to FIG. 4A through FIG. 4D, FIG. 4G, and FIG. 4H may each be performed to generate an array of pads 30 (each having the primers 22A, 22B attached thereof) separated by hydrophobic interstitial regions 50 across the hydrophobic layer 20.

Referring now to FIG. 5A through FIG. 5E, still another example of the method is depicted. This method generally includes defining a depression 28 in a first (sacrificial) resin layer 26 that is resistant to silanization in an organic solvent; defining a second resin layer 14 over the first resin layer 26, including in the depression 28, the second resin layer 14 being reactive toward silanization in the organic solvent, and the first resin layer 26 and the second resin layer 14 being orthogonally etchable; anisotropically etching, using a fluorinated plasma, the second resin layer 14 to expose a surface (in this example interstitial regions 32) of the first resin layer 26, thereby leaving a portion 40 of the second resin layer 14 in the depression 28; and contacting exposed surfaces of the first resin layer 26 and the portion of the second resin layer 14 to a silane in the organic solvent, thereby selectively silanizing the exposed surface of the portion of the second resin layer 14.

In the example shown in FIG. 5A through FIG. 5E, the first/sacrificial resin layer 26 may be supported by the base support 16′. Any example of the base support 16′ may be used.

Defining the depression 28 in the first/sacrificial resin layer 26 is generally shown in FIG. 5A and FIG. 5B and involves depositing any example of the acrylate, fluorinated, or organic epoxy resin composition 25 on the base support 16′, imprinting the acrylate fluorinated, or organic epoxy resin composition 25 with the working stamp 34 having a negative replica of the depression 28; and photocuring the acrylate, fluorinated, or organic epoxy resin composition 25 while the working stamp 34 is in place, thereby forming the first resin layer 26 having the depression 28 defined therein. Resin composition 25 deposition and patterning may be accomplished as described in any of the examples disclosed herein.

As shown in FIG. 5C, the second resin layer 14 is then formed over the first/sacrificial resin layer 26, including in the depression 28. To form the second resin layer 14, the epoxy siloxane resin composition is deposited and cured as described, for example, in reference to the methods shown in FIG. 2A through FIG. 2G.

The second resin layer 14 is then exposed to anisotropic etching using fluorinated plasma. The second resin layer 14 is susceptible to the fluorinated plasma. As such, the entire exposed surface of the second resin layer 14 is etched until the underlying sacrificial resin layer 26 is exposed. The sacrificial resin layer 26 is not susceptible to the fluorinated plasma, as it is orthogonally etchable to the second resin layer 14. Thus, the surface (interstitial regions 32) of the sacrificial resin layer 26 acts as an etch stop. As shown in FIG. 5D, a portion 40 of the resin layer 14 remains in the depression 28 after the fluorinated plasma is stopped. Also as shown in FIG. 5D, the reactive groups 36 of the resin layer 14 remain intact.

The reactive groups 36 of the resin layer 14 and the interstitial regions 32 of the first/sacrificial resin layer 26 exhibit orthogonal silane solution reactivity. As such, the structure shown in FIG. 5D can be exposed to a silane in an organic solvent, which selectively silanizes the surface of the resin layer 14, but does not silanize interstitial regions 32 of the first/sacrificial resin layer 26. In one example, the silane is norbornene silane and the organic solvent is acetonitrile. The silane solution may be allowed to react at a temperature ranging from about 15° C. to about 30° C. for a time ranging from about 15 minutes to about 4 hours. The surface of the structure may then be rinsed. After silane solution exposure, it is to be understood that the surface of the resin layer 14 is silanized, and the interstitial regions 32 of the first/sacrificial resin layer 26 remain unaffected by the silane. The silanized layer 38 is depicted in FIG. 5E.

Referring now to FIG. 5E, the method further includes applying the polymeric hydrogel 24 to the silanized surface 38 of the resin layer 14. In this example, the polymeric hydrogel 24 may be any of the gel materials described herein and may be applied using any suitable deposition technique and cured. As shown in FIG. 5E, the polymeric hydrogel 24 is applied over the silanized surface 38, but is not applied over the interstitial regions 32 of the first/sacrificial resin layer 26. The polymeric hydrogel 24 covalently attaches to the silanized surface 38, but does not covalently attach to the interstitial regions 32. Because of the different interactions at the surface 38 and at the interstitial regions 32, the polymeric hydrogel 24 remains over the surface 38, and can be easily removed (e.g., via sonication, washing, wiping, etc.) from the interstitial regions 32. Thus, the interstitial regions 32 are not exposed to polishing.

As shown in FIG. 5E, the primers 22A, 22B are grafted to the polymeric hydrogel 24. The primers 22A, 22B may be grafted after the polymeric hydrogel 24 is applied using any of the grafting techniques set forth herein. In other examples, the primers 22A, 22B may be pre-grafted to the polymeric hydrogel 24. In these examples, additional primer grafting is not performed.

Sequencing Methods

All of the flow cell architectures disclosed herein can support sequential paired end sequencing.

When examples of the flow cell 10 are used in sequencing, template strands (not shown) that are to be sequenced may be formed using the primers 22A, 22B.

Prior to template strand formation, library templates may be prepared from any nucleic acid sample (e.g., a DNA sample or an RNA sample). The DNA nucleic acid sample may be fragmented into single-stranded, similarly sized (e.g., <1000 bp) DNA fragments. The RNA nucleic acid sample may be used to synthesize complementary DNA (cDNA), and the cDNA may be fragmented into single-stranded, similarly sized (e.g., <1000 bp) cDNA fragments. During preparation, adapters may be added to the ends of any of the fragments. Through reduced cycle amplification, different motifs may be introduced in the adapters, such as sequencing primer binding sites, indices, and regions that are complementary to the primers 22A, 22B. In some examples, the fragments from a single nucleic acid sample have the same adapters added thereto. The final library templates include the DNA or cDNA fragment and adapters at both ends. The DNA or cDNA fragment represents the portion of the final library template that is to be sequenced.

A plurality of library templates may be introduced to the flow cell 10. Multiple library templates are hybridized, for example, to one of two types of primers 22A, 22B.

Cluster generation may then be performed. In one example of cluster generation, the library templates are copied from the hybridized primers by 3′ extension using a high-fidelity DNA polymerase. The original library templates are denatured, leaving the copies immobilized to the primers 22A, 22B. Isothermal bridge amplification or some other form of amplification may be used to amplify the immobilized copies. For example, the copied templates loop over to hybridize to an adjacent, complementary primer, and a polymerase copies the copied templates to form double stranded bridges, which are denatured to form two single stranded strands. These two strands loop over and hybridize to adjacent, complementary primers and are extended again to form two new double stranded loops. The process is repeated on each template copy by cycles of isothermal denaturation and amplification to create dense clonal clusters. Each cluster of double stranded bridges is denatured. In an example, the reverse strand is removed by specific base cleavage, leaving forward template strands. Clustering results in the formation of several template strands immobilized in the depressions 28 or on the pads 30. This example of clustering is referred to as bridge amplification, and is one example of the amplification that may be performed. It is to be understood that other amplification techniques may be used, such as the exclusion amplification (Examp) workflow (Illumina Inc.).

A sequencing primer (not shown) may be introduced that hybridizes to a complementary portion of the sequence of the template strand. This sequencing primer renders the template strand ready for sequencing.

An incorporation mix including labeled nucleotides may then be introduced into the flow cell 10, e.g., via an input port. In addition to the labeled nucleotides, the incorporation mix may include water, a buffer, and polymerases capable of nucleotide incorporation. When the incorporation mix is introduced into the flow cell 10, the mix enters the flow channel 12, and contacts the depressions 28 or pads 30 where the template strands are present.

The incorporation mix is allowed to incubate in the flow cell 10, and labeled nucleotides are incorporated by respective polymerases into the nascent strands along the template strands. During incorporation, one of the labeled nucleotides is incorporated, by a respective polymerase, into one nascent strand that extends one sequencing primer and that is complementary to one of the template strands. Incorporation is performed in a template strand dependent fashion, and thus fluorescence detection of type of labeled nucleotides added to the nascent strand can be used to determine the sequence of the template strand. Incorporation occurs in at least some of the template strands across the flow cell substrate(s) during a single sequencing cycle.

The incorporated labeled nucleotides may include a reversible termination property due to the presence of a 3′ OH blocking group, which terminates further sequencing primer extension once the labeled nucleotide has been added. After a desired time for incubation and incorporation, the incorporation mix, including non-incorporated labeled nucleotides, may be removed from the flow cell 10 during a wash cycle. The wash cycle may involve a flow-through technique, where a washing solution (e.g., buffer) is directed into, through, and then out of flow channel, e.g., by a pump or other suitable mechanism.

Without further incorporation taking place, the most recently incorporated optical-labeled nucleotides can be detected through an imaging event. During the imaging event, an illumination system (not shown) may provide an excitation light to the flow cell substrates. The optical (e.g., dye) labels of the incorporated labeled nucleotides emit fluorescence in response to the excitation light.

After imaging is performed, a cleavage mix may then be introduced into the flow cell 10. In an example, the cleavage mix is capable of i) removing the 3′ OH blocking group from the incorporated nucleotides, and ii) cleaving the dye label from the incorporated nucleotide. Examples of 3′ OH blocking groups and suitable de-blocking agents/components in the cleavage mix may include: ester moieties that can be removed by base hydrolysis; allyl-moieties that can be removed with NaI, chlorotrimethylsilane and Na₂S₂O₃ or with Hg(II) in acetone/water; azidomethyl which can be cleaved with phosphines, such as tris(2-carboxyethyl)phosphine (TCEP) or tris(hydroxypropyl)phosphine (THP); acetals, such as tert-butoxy-ethoxy which can be cleaved with acidic conditions; MOM (—CH₂OCH₃) moieties that can be cleaved with LiBF₄ and CH₃CN/H₂O; 2,4-dinitrobenzene sulfenyl which can be cleaved with nucleophiles such as thiophenol and thiosulfate; tetrahydrofuranyl ether which can be cleaved with Ag(I) or Hg(II); and 3′ phosphate which can be cleaved by phosphatase enzymes (e.g., polynucleotide kinase). Examples of suitable dye label cleaving agents/components in the cleavage mix may include: sodium periodate, which can cleave a vicinal diol; phosphines, such as tris(2-carboxyethyl)phosphine (TCEP) or tri(hydroxypropyl)phosphine (THP), which can cleave azidomethyl linkages; palladium and THP, which can cleave an allyl; bases, which can cleave ester moieties; or any other suitable cleaving agent.

Additional sequencing cycles may then be performed until the template strands are sequenced.

To further illustrate the present disclosure, examples are given herein. It is to be understood that these example are provided for illustrative purposes and are not to be construed as limiting the scope of the present disclosure.

### NON-LIMITING WORKING EXAMPLES

### Example 1

An acrylate resin and an organic epoxy resin (each of which was etchable using air plasma) were prepared and used as sacrificial layers.

For the acrylate example, an etch-resistant acrylate resin was deposited on a silicon substrate and was patterned using nanoimprint lithography. The sacrificial acrylate resin included pentaerythritol triacrylate, DPBAPO in an amount ranging from about 1 mass % to about 5 mass % of the total solid content, and BYK®-350 in an amount ranging from about 1 mass % to about 3 mass % of the total solid content. The solid mix was dissolved in propylene glycol methyl ether acetate (PGMEA) to form a solution including from about 17% to about 25% solids. The solution was then spin-coated on the etch-resistant acrylate resin. The resultant coating was cured under a working stamp UV cure using a 365 nm UV LED light source with a 330 mW/cm² power output measured at the sample level.

For the organic epoxy example, an etch-resistant epoxy siloxane resin was deposited on a glass substrate and was patterned using nanoimprint lithography. The sacrificial organic epoxy resin included from 50 mass % to less than 100 mass % (based on monomer content) of trimethylolpropane triglycidyl ether and greater than 0 mass % to 50 mass % (based on monomer content) of 3,4-epoxycyclohexylmethyl 3,4-epoxycyclohexanecarboxylate, a combination of PAG-290 and IPF in a total amount ranging from about 1 mass % to about 5 mass % of the total solid content, and BYK®-350 in an amount ranging from about 1 mass % to about 3 mass % of the total solid content. The solid mix was dissolved in propylene glycol methyl ether acetate (PGMEA) to form a solution including from about 17% to about 25% solids. The solution was then spin-coated on the etch-resistant, epoxy siloxane resin. The resultant coating was cured under a working stamp UV cure using a 365 nm UV LED light source with a 330 mW/cm² power output measured at the sample level.

Both the acrylate example and the organic epoxy example were exposed to air plasma etching for 2 to 3 minutes to determine if the sacrificial acrylate resin and the sacrificial organic epoxy resin could be removed without deleteriously affecting the patterned, etch-resistant acrylate resin and the patterned, etch-resistant epoxy siloxane resin. While the results are not reproduced herein, scanning electron microscopy (SEM) images of the patterned, etch-resistant acrylate resin and the patterned, etch-resistant epoxy siloxane resin after air plasma etching demonstrated that both the sacrificial acrylate resin and the sacrificial organic epoxy resin could be effectively removed while leaving the pattern of the etch-resistant resins intact.

The sacrificial organic epoxy resin was also spin coated on a glass wafer and was patterned using nanoimprint lithography. The glass wafer was ultrasonicated in dimethylsulfoxide (DMSO) at 80 kHz for about 60 minutes. While the results are not reproduced herein, atomic force microscopy (AFM) images of the imprint before and after ultrasonication indicated that the resin was partially lifted off. The sonication frequency, the sonication temperature, and the solvent composition may be adjusted to achieve full dissolution and removal of the sacrificial organic epoxy resin.

### Example 2

Multiple glass wafers were exposed to plasma ashing (30 seconds, 100 W RF power) to activate the surface. A silane coupling agent was deposited on each glass wafer, followed by heating at 130° C. for 2 minutes. A layer of an epoxy siloxane resin (including epoxy polyhedral oligomeric silsesquioxane, 2 initiators (PAG 290 and IPF), BYK®-350, and PGMEA) was spin coated on each glass wafer, soft baked (at 130° C. for 2 minutes), and cured with UV light (365 nm).

For Ex. 1, a sacrificial fluorinated resin was patterned over the photocured epoxy siloxane resin. The sacrificial acrylate resin composition included a bifunctional polyfluoro-polyethylene-urethane methacrylate, two free radical photoinitiators (phenylbis(2,4,6-,trimethylbenzoyl)phosphine oxide and ethyl(2,4,6-trimethylbenzoyl)phenylphosphinate), BYK®-350, and butyl acetate. The total solids ranged from about 15% to about 25% solids.

For Ex. 2, a sacrificial acrylate resin was patterned over the photocured epoxy siloxane resin. The sacrificial acrylate resin composition included glycerol 1,3-diglycerolate diacrylate, two free radical photoinitiators (phenylbis(2,4,6-,trimethylbenzoyl)phosphine oxide and ethyl(2,4,6-trimethylbenzoyl)phenylphosphinate), BYK®-350, and PGMEA. The total solids ranged from about 15% to about 25% solids.

For patterning the respective examples with depressions, a layer of the sacrificial acrylate resin composition or a layer of the sacrificial fluorinated resin composition was spin coated on the photocured epoxy siloxane resin and soft baked (at 130° C. for 2 minutes). A working stamp was pressed into the sacrificial acrylate resin composition or the sacrificial fluorinated resin composition, and the respective resin composition was cured with UV light (365 nm) while the working stamp was in place. The working stamp was then peeled from the respective photocured resin.

For Comp. Ex. 3, no sacrificial resin composition was used. As such, the comparative example included the photocured epoxy siloxane resin over the glass wafer.

Each of Ex. 1, Ex. 2 and Comp. Ex. 3 was reacted with norbornene silane by incubating the respective structures at room temperature for 30 minutes in a 20% solution in acetonitrile, followed by rinsing, drying and allowing it to rest for 1 hour at room temperature. The norbornene groups were then further reacted with a fluorescent tetrazine to quantify the degree of silanization. A 20 μM aqueous solution of sulfo-cyanine 3 tetrazine was used to incubate the samples at room temperature for 30 minutes, which was followed by water rinsing and fluorescent scanning.

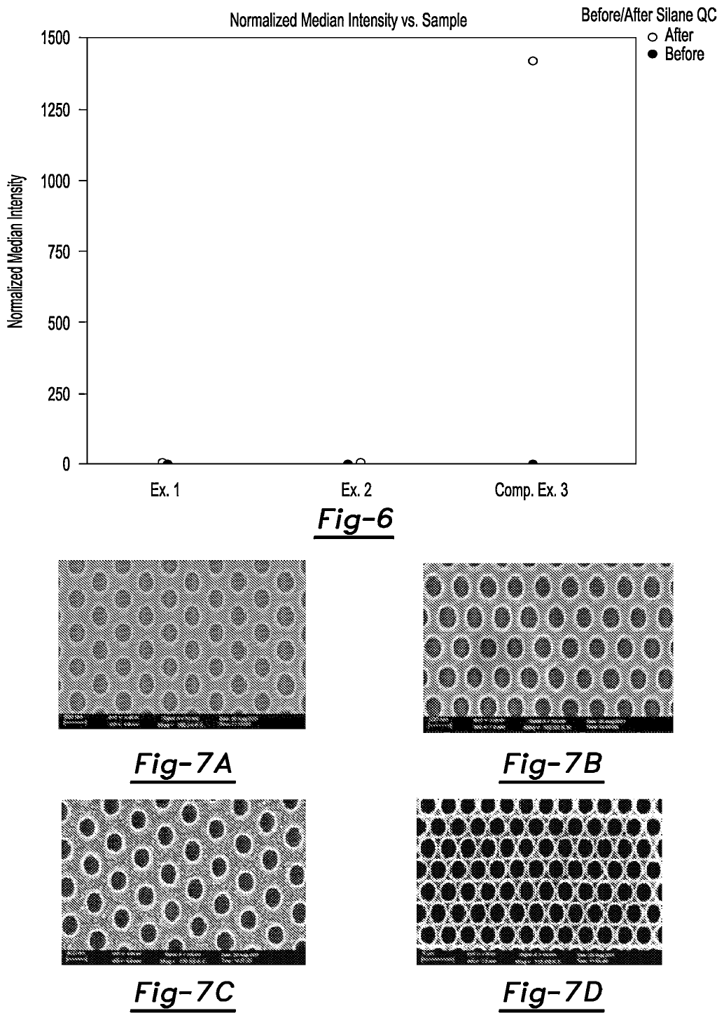

While the fluorescent scanning images are not reproduced herein, the extracted intensities from a portion of each of Ex. 1, Ex. 2 and Comp. Ex. 3 is shown in FIG. 6. Both the fluorescent scanning images and the extracted intensities indicated that the photocured sacrificial acrylate resin and the photocured sacrificial fluorinated resin were resistant to silanization and remained nearly intact after silanization. In contrast, the fluorescent scanning images and the extracted intensities for Comp. Ex. 3 indicated that the photocured epoxy siloxane resin readily reacted with the silane. These results illustrate the orthogonal solution silanization between examples of the sacrificial resins and the photocured epoxy siloxane resin.

### Example 3

Ex. 4 and Ex. 5 were prepared in the same manner, respectively, as Ex. 1 and Ex. 2 in Example 2.

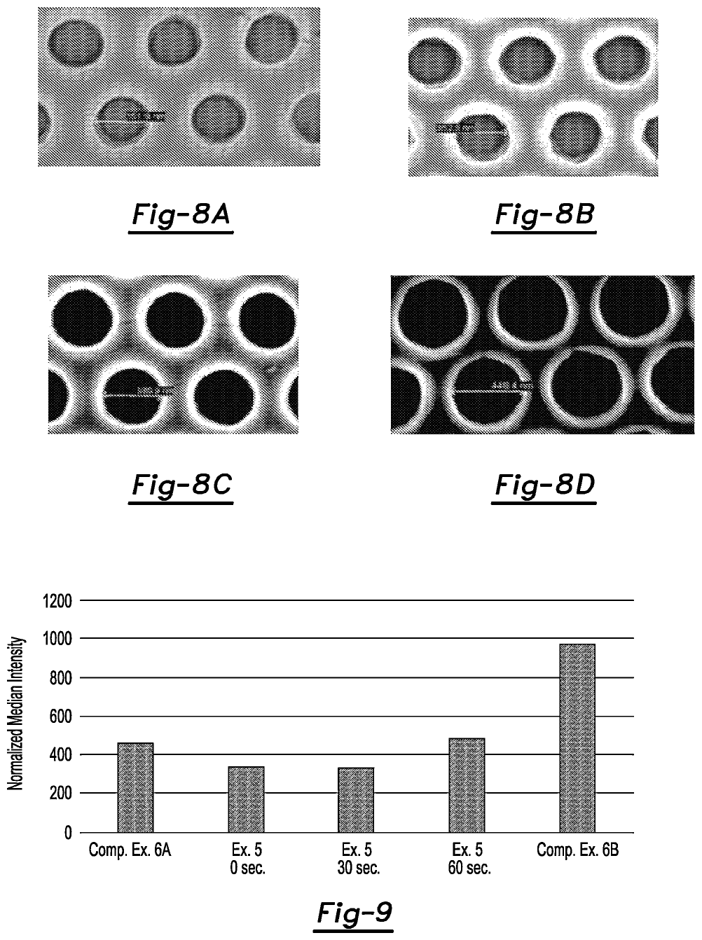

In this example, the depressions in the photocured sacrificial acrylate resin and the photocured sacrificial fluorinated resin did not extend through to the underlying photocured epoxy siloxane resins. Each of the examples was exposed to an ash time titration, which involved exposure to air plasma for different times up to 120 seconds. SEM images were taken before etching (0 seconds) and at different intervals once etching began (30 seconds, 60 seconds, and 120 seconds). The images for Ex. 4 (including the photocured sacrificial acrylate resin) and the images for Ex. 5 (including the photocured sacrificial fluorinated resin) are shown in FIGS. 7A-7D and FIG. 8A-8D, respectively. It is noted that the oval shape of Ex. 4 was due to a temporary imaging artifact. The results illustrated that ashing did expose the underlying photocured epoxy siloxane resin in each of the depression. The plasma conditions were significantly isotropic; and the results illustrated that anisotropicity, which can be tuned by carrying the ashing feed gas, the pressure, and the plasma density, would help to maintain the original depression pattern.

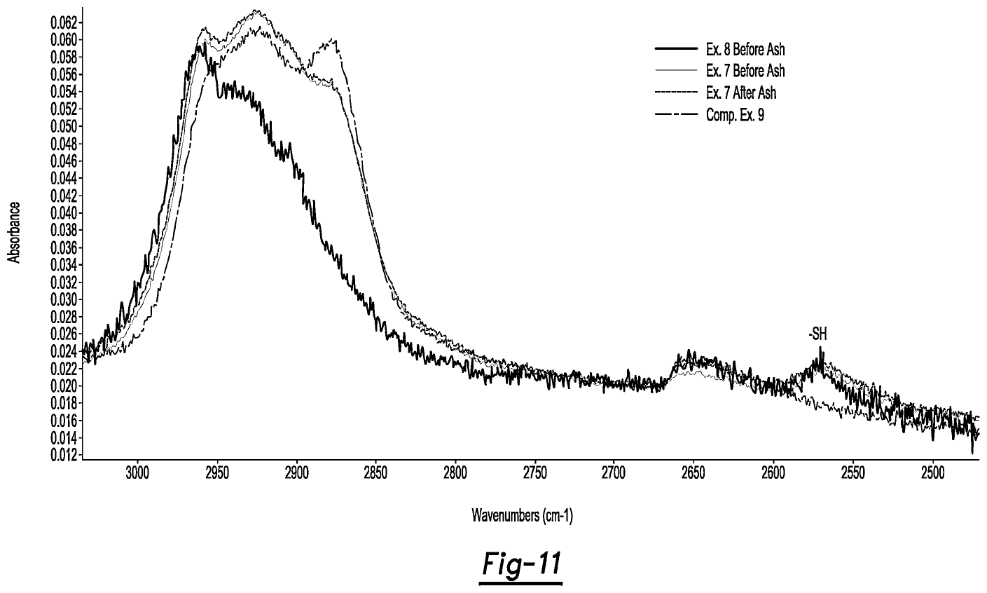

Ex. 5 was then exposed to the same silanization and quantification process described in Example 2 (i.e., immersion in 20% norbornene silane solution in acetonitrile, followed by norbornene group detection with fluorescent sulfo-cyanine 3 tetrazine). For comparison, Comp. Ex. 6A, which included a non-patterned photocured epoxy siloxane resin over the glass wafer, and Comp. Ex. 6B, which included a patterned photocured epoxy siloxane resin over the glass wafer, were also exposed to silanization and quantification. The extracted intensities from the depressions of Ex. 5, from a portion of Comp. Ex. 6A, and from the depressions of Comp. Ex. 6B are shown in FIG. 9. The results for Ex. 5 in FIG. 9 illustrate an increase in intensity with an increase in plasma ashing time, which corresponds to the fact that an increasing amount of the underlying photocured epoxy siloxane resin was exposed as a result of residual photocured sacrificial fluorinated resin being etched from the depression and depression diameter increase (due to etching anisotropy). It is also noted that the patterned epoxy siloxane resin (Comp. Ex. 6B) had the highest intensity as the depressions increased the surface area of the epoxy siloxane resin.

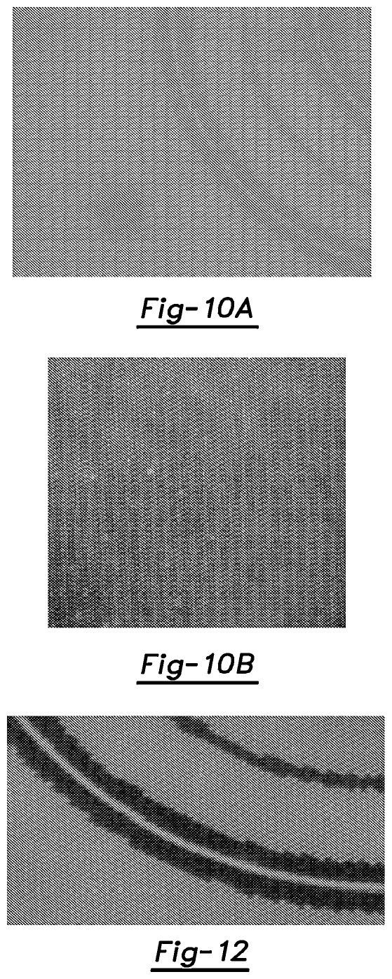

From this analysis, Ex. 5 exposed to 60 seconds of plasma ashing was selected to demonstrate fluorescence coming from the depressions (where the photocured epoxy siloxane resin was exposed) but not coming from the interstitial regions (where the photocured sacrificial fluorinated resin remained). The structure was characterized with a higher resolution microscope (100× magnification, oil immersion, LED illumination), and the images are reproduced in black and white in FIG. 10A and FIG. 10B. In these images, the depressions exhibited fluorescence while the interstitial regions and fiducial marks did not exhibit fluorescence, indicating that the photocured sacrificial fluorinated resin was not silanized and thus is orthogonally functionalizable relative to the photocured epoxy siloxane resin.

### Example 4

Two thiol-ene resins were used in this example.

The first thiol-ene resin composition included a mixture of about 39 mass % glycerol 1,3-diglycerolate diacrylate and about 57 mass % pentaerythritol tetrakis(3-mercaptopropionate), about 2 mass % 2-hydroxy-2-methylpropiophenone, a mixture of about 1 mass % phenyl dihydrogen phosphate and about 1 mass % benzene-1,2,3-triol, BYK®-350 in an amount ranging from about 1 mass % to about 3 mass % of the total solid content, and PGMEA. The total solids ranged from about 15% to about 25% solids.

The second thiol-ene resin composition included a mixture of about 39 mass % pentaerythritol triacrylate and about 57 mass % pentaerythritol tetrakis(3-mercaptopropionate), about 2 mass % 2-hydroxy-2-methylpropiophenone, a mixture of about 1 mass % phenyl dihydrogen phosphate and about 1 mass % benzene-1,2,3-triol, BYK®-350 in an amount ranging from about 1 mass % to about 3 mass % of the total solid content, and PGMEA. The total solids ranged from about 15% to about 25% solids.

An acrylate resin composition was used for comparison. The acrylate formulation was the same as Ex. 2 in Example 2.

Each of the resin compositions was spin coated on a glass wafer and was soft baked (at 130° C. for 2 minutes). A working stamp was pressed into the respective composition, and the respective resin composition was cured with UV light (365 nm) while the working stamp was in place. The working stamp was then peeled from the respective photocured resin. The imprint generated with the first thiol-ene resin composition is Ex. 7, the imprint generated with the second thiol-ene resin composition is Ex. 8, and the imprint generated with the acrylate resin composition is Comp. Ex. 9. Ex. 7 was also exposed to 30 seconds of air plasma ashing.

Fourier transform infrared spectroscopy (FTIR) was performed on Ex. 7 (before and after air plasma ashing), on Ex. 8 (before air plasma ashing), and on Comp. Ex. 9. The results are shown in FIG. 11. The results for Ex. 7 demonstrate that residual thiol groups remained after air plasma ashing.

### Example 5

The second thiol-ene resin composition from Example 4 was used in this example. The thiol-ene resin composition was spin coated on a glass wafer and was UV cured with 10 second exposure.

The sacrificial acrylate resin composition from Example 1 was also used. The sacrificial acrylate resin composition was deposited over the photocured thiol-ene resin, and was patterned with initial depressions using nanoprint lithography. More particularly, the sacrificial acrylate resin was spin coated on the photocured thiol-ene resin and was soft baked (at 130° C. for 2 minutes). A working stamp was pressed into the sacrificial acrylate resin, and the resin composition was cured with UV light (365 nm) while the working stamp was in place (10 second exposure). The working stamp was then peeled from the photocured sacrificial acrylate resin.

The residual photocured sacrificial acrylate resin in the initial depressions was air plasma ashed (30 seconds, 594 W) to expose the underlying photocured thiol-ene resin. The thiol groups were reacted using base catalyzed Michael addition with the fluorescein. The acrylate interstitials were not expected to react with the fluorescein under these conditions, and thus were expected to remain dark.

The structure was imaged using a NIKON microscope at 100× magnification with oil immersion and LED illumination. A portion of the image is reproduced in black and white in FIG. 12. The fluorescent monomer was found to selectively deposit on the reactive resin within the depressions (see the lighter regions in FIG. 12), while the interstitial regions and the fiducials formed of the non-reactive sacrificial acrylate resin not react with the fluorescent dye (see the darker regions in FIG. 12). These results demonstrate that the multilayer stack built from a thiol-ene resin and a sacrificial acrylate resin is capable of selective depression functionalization.

### ADDITIONAL NOTES

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

While several examples have been described in detail, it is to be understood that the disclosed examples may be modified. Therefore, the foregoing description is to be considered non-limiting.

1. A method, comprising:
defining an initial depression in a first resin layer of a multi-layer stack including the first resin layer over a second resin layer or a base support, the first resin layer being resistant to silanization in an organic solvent, the second resin layer or the base support being reactive toward silanization in the organic solvent, and the first resin layer and the second resin layer or the base support being orthogonally etchable;
anisotropically etching, using air or O₂ plasma, through a remaining portion of the first resin layer at the initial depression to expose a surface of the second resin layer or the base support and to form a depression; and
exposing the multi-layer stack to a silane in the organic solvent, thereby selectively silanizing the surface of the second resin layer or the base support at the depression.

2. The method as defined in claim 1, wherein:
the multi-layer stack includes the first resin layer over the second resin layer;
the first resin layer is selected from the group consisting of a photocured acrylate resin composition, a photocured fluorinated resin composition, and a photocured organic epoxy resin composition; and
the second resin layer is a photocured siloxane-based resin composition.

3. The method as defined in claim 2, wherein defining the initial depression involves:
depositing an acrylate resin composition on the second resin layer, the acrylate resin composition including:
an acrylate monomer selected from the group consisting of glycerol dimethacrylate, mixture of isomers; pentaerythritol triacrylate; glycerol 1,3-diglycerolate diacrylate; pentaerythritol tetraacrylate; and combinations thereof;
a radical photoinitiator;
a surface additive; and
a solvent;
imprinting the acrylate resin composition with a working stamp having a negative replica of the initial depression; and
photocuring the acrylate resin composition while the working stamp is in place, thereby forming the photocured acrylate resin composition having the initial depression defined therein.

4. The method as defined in claim 2, wherein defining the initial depression involves:
depositing a fluorinated resin composition on the second resin layer, the fluorinated resin composition including:
a fluorinated monomer selected from the group consisting of a bifunctional polyfluoro-polyethylene-urethane methacrylate; 2,2,3,3,4,4,5,5-octafluoro-1,6-hexanediol diacrylate; and combinations thereof;
a radical photoinitiator;
a surface additive; and
a solvent;
imprinting the fluorinated resin composition with a working stamp having a negative replica of the initial depression; and
photocuring the fluorinated resin composition while the working stamp is in place, thereby forming the photocured fluorinated resin composition having the initial depression defined therein.

5. The method as defined in claim 2, wherein the photocured siloxane-based resin composition is formed from an epoxy siloxane resin composition including a monomer or cross-linkable copolymer selected from the group consisting of an epoxy functionalized silsesquioxane; tetrakis(epoxycyclohexyl ethyl)tetramethyl cyclotetrasiloxane; a copolymer of (epoxycyclohexylethyl)methylsiloxane and dimethylsiloxane; 1,3-bis[2-(3,4-epoxycyclohexyl) ethyl] tetramethyl disiloxane; 1,3-bis(glycidoxypropyl)tetramethyl disiloxane; and combinations thereof.

6. The method as defined in claim 2, wherein defining the initial depression involves:
depositing an organic epoxy resin composition on the second resin layer, the organic epoxy resin composition including:
a monomer or cross-linkable copolymer selected from the group consisting of trimethylolpropane triglycidyl ether; 3,4-epoxycyclohexylmethyl-3,4-epoxycyclo-hexanecarboxylate; bis((3,4-epoxycyclohexyl)methyl) adipate; 4-vinyl-1-cyclohexene 1,2-epoxide; vinylcyclohexene dioxide; 4,5-epoxytetrahydrophthalic acid diglycidylester; 1,2-epoxy-3-phenoxypropane; glycidyl methacrylate; 1,2-epoxyhexadecane; poly(ethylene glycol) diglycidylether; pentaerythritol glycidyl ether; diglycidyl 1,2-cyclohexanedicarboxylate; tetrahydrophthalic acid diglycidyl ester; and combinations thereof;
an initiating system selected from the group consisting of a direct photoacid generator and a combination of a free radical photoinitiator and a photoacid generator; and
a solvent;
imprinting the organic epoxy resin composition with a working stamp having a negative replica of the initial depression; and
photocuring the organic epoxy resin composition while the working stamp is in place, thereby forming the photocured organic epoxy resin composition having the initial depression defined therein.

7. The method as defined in claim 1, wherein the silane is norbornene silane and the organic solvent is acetonitrile.

8. The method as defined in claim 1, wherein:
the multi-layer stack includes the first resin layer over the base support;
the first resin layer is selected from the group consisting of a photocured acrylate resin composition, a photocured fluorinated resin composition and a photocured organic epoxy resin composition; and
the base support is glass.

9. The method as defined in claim 1, further comprising applying a polymeric hydrogel to the silanized surface of the second resin layer or the base support at the depression.

10. The method as defined in claim 1, wherein prior to exposing the multi-layer stack to the silane, the method further comprises anisotropically etching, using fluorinated plasma, the second resin layer or the base support at the depression to extend the depression a predetermined distance into the second resin layer or the base support.

11. A method, comprising:
defining a depression in a first resin layer that is resistant to silanization in an organic solvent;
defining a second resin layer over the first resin layer, including in the depression, the second resin layer being reactive toward silanization in the organic solvent, and the first resin layer and the second resin layer being orthogonally etchable;
anisotropically etching, using a fluorinated plasma, the second resin layer to expose a surface of the first resin layer, thereby leaving a portion of the second resin layer in the depression; and
contacting exposed surfaces of the first resin layer and the portion of the second resin layer to a silane in the organic solvent, thereby selectively silanizing the exposed surface of the portion of the second resin layer.

12. The method as defined in claim 11, wherein defining the depression involves:
depositing an acrylate resin composition on a base support, the acrylate resin composition including:
an acrylate monomer selected from the group consisting of glycerol dimethacrylate, mixture of isomers; pentaerythritol triacrylate; glycerol 1,3-diglycerolate diacrylate; pentaerythritol tetraacrylate; and combinations thereof;
a radical photoinitiator;
a surface additive; and
a solvent;
imprinting the acrylate resin composition with a working stamp having a negative replica of the depression; and
photocuring the acrylate resin composition while the working stamp is in place, thereby forming the first resin layer having the depression defined therein.

13. The method as defined in claim 11, wherein defining the depression involves:
depositing a fluorinated resin composition on a base support, the fluorinated resin composition including:
a fluorinated monomer selected from the group consisting of a bifunctional polyfluoro-polyethylene-urethane methacrylate; 2,2,3,3,4,4,5,5-octafluoro-1,6-hexanediol diacrylate; and combinations thereof;
a radical photoinitiator;
a surface additive; and
a solvent;
imprinting the fluorinated resin composition with a working stamp having a negative replica of the depression; and
photocuring the fluorinated resin composition while the working stamp is in place, thereby forming the first resin layer having the depression defined therein.

14. The method as defined in claim 11, wherein defining the depression involves:
depositing an organic epoxy resin composition on a base support, the organic epoxy resin composition including:
a monomer or cross-linkable copolymer selected from the group consisting of trimethylolpropane triglycidyl ether; 3,4-epoxycyclohexylmethyl-3,4-epoxycyclo-hexanecarboxylate; bis((3,4-epoxycyclohexyl)methyl) adipate; 4-vinyl-1-cyclohexene 1,2-epoxide; vinylcyclohexene dioxide; 4,5-epoxytetrahydrophthalic acid diglycidylester; 1,2-epoxy-3-phenoxypropane; glycidyl methacrylate; 1,2-epoxyhexadecane; poly(ethylene glycol) diglycidylether; pentaerythritol glycidyl ether; diglycidyl 1,2-cyclohexanedicarboxylate; tetrahydrophthalic acid diglycidyl ester; and combinations thereof;
an initiating system selected from the group consisting of a direct photoacid generator and a combination of a free radical photoinitiator and a photoacid generator; and
a solvent;
imprinting the organic epoxy resin composition with a working stamp having a negative replica of the depression; and
photocuring the organic epoxy resin composition while the working stamp is in place, thereby forming the first resin layer having the depression defined therein.

15. The method as defined in claim 11, wherein defining the second resin layer over the first resin layer, involves:
depositing an epoxy siloxane resin composition including a monomer or cross-linkable copolymer selected from the group consisting of an epoxy functionalized silsesquioxane; tetrakis(epoxycyclohexyl ethyl)tetramethyl cyclotetrasiloxane; a copolymer of (epoxycyclohexylethyl)methylsiloxane and dimethylsiloxane; 1,3-bis[2-(3,4-epoxycyclohexyl) ethyl] tetramethyl disiloxane; 1,3-bis(glycidoxypropyl)tetramethyl disiloxane; and combinations thereof; and
photocuring the deposited epoxy siloxane resin composition.

16. The method as defined in claim 11, wherein the silane is norbornene silane and the organic solvent is acetonitrile.

17. The method as defined in claim 11, further comprising applying a polymeric hydrogel to the silanized surface of the portion of the second resin layer.

18.-24. (canceled)

25. A method, comprising:
defining an initial depression in a first resin layer of a multi-layer stack including the first resin layer over a second resin layer over a base support, the first resin layer including a first functional group that is non-reactive with sequencing surface chemistry and the second resin layer including a second functional group that is reactive with the sequencing surface chemistry;
anisotropically etching, using air or O₂ plasma, through a remaining portion of the first resin layer at the initial depression to expose a surface of the second resin layer and form a depression, whereby the second functional group remains reactive; and
exposing the multi-layer stack to the surface chemistry, thereby attaching the sequencing surface chemistry to the second functional group.

26. The method as defined in claim 25, wherein:
prior to defining the initial depression, the method further comprises forming the multi-layer stack by:
depositing a thiol-ene resin composition on the base support, the thiol-ene resin composition including:
from greater than 0 mass % to less than 50 mass %, based on a total monomer content of the thiol-ene resin composition, of an acrylate monomer;
from greater than 50 mass % to less than 100 mass % based on the total monomer content of the thiol-ene resin composition, of a thiol monomer selected from the group consisting of pentaerythritol tetrakis(3-mercaptopropionate), 1,4-bis(3-mercaptobutyryloxy)butane, and trimethylolpropane tris(3-mercaptopropionate);
a radical photoinitiator;
an acidic stabilizer, a radical stabilizer, or combinations thereof;
an optional surface additive; and
a solvent;
photocuring the thiol-ene resin composition, thereby forming the second resin layer; and
depositing an acrylate resin composition, a fluorinated resin composition, or an organic epoxy resin composition on the second resin layer; and
defining the initial depression includes:
imprinting the acrylate resin composition, the fluorinated resin composition, or the organic epoxy resin composition with a working stamp having a negative replica of the initial depression; and
photocuring the acrylate resin composition, the fluorinated resin composition, or the organic epoxy resin composition while the working stamp is in place, thereby forming the first resin layer having the initial depression defined therein.

27. (canceled)

28. The method as defined in claim 25, wherein prior to exposing the multi-layer stack to the sequencing surface chemistry, the method further comprises anisotropically etching, using fluorinated plasma, the second resin layer at the depression to extend the depression a predetermined distance into the second resin layer.

29. (canceled)


SEQUENCE LISTING (13 sequences)

SEQ ID NO: 1 - DNA, 29 bp, synthetic construct
  source 1..29: mol_type = other DNA
  modified_base 23: mod_base = OTHER; note = uracil
aatgatacggcgaccaccgagatctacac

SEQ ID NO: 2 - DNA, 24 bp, synthetic construct
  source 1..24: mol_type = other DNA
  modified_base 22: mod_base = OTHER; note = 8-oxoguanine
caagcagaagacggcatacganat

SEQ ID NO: 3 - DNA, 24 bp, synthetic construct
  source 1..24: mol_type = other DNA
  modified_base 20: mod_base = OTHER; note = 8-oxoguanine
caagcagaagacggcatacnagat

SEQ ID NO: 4 - DNA, 24 bp, synthetic construct
  modified_base 20: mod_base = OTHER; note = 8-oxoguanine
  modified_base 22: mod_base = OTHER; note = 8-oxoguanine
  source 1..24: mol_type = other DNA
caagcagaagacggcatacnanat

SEQ ID NO: 5 - DNA, 29 bp, synthetic construct
  modified_base 23: mod_base = OTHER; note = allyl modified T
  source 1..29: mol_type = other DNA
aatgatacggcgaccaccgaganctacac

SEQ ID NO: 6 - DNA, 35 bp, synthetic construct
  source 1..35: mol_type = other DNA
gctggcacgtccgaacgcttcgttaatccgttgag

SEQ ID NO: 7 - DNA, 35 bp, synthetic construct
  source 1..35: mol_type = other DNA
ctcaacggattaacgaagcgttcggacgtgccagc

SEQ ID NO: 8 - DNA, 35 bp, synthetic construct
  source 1..35: mol_type = other DNA
cgtcgtctgccatggcgcttcggtggatatgaact

SEQ ID NO: 9 - DNA, 35 bp, synthetic construct
  source 1..35: mol_type = other DNA
agttcatatccaccgaagcgccatggcagacgacg

SEQ ID NO: 10 - DNA, 35 bp, synthetic construct
  source 1..35: mol_type = other DNA
acggccgctaatatcaacgcgtcgaatccgcaact

SEQ ID NO: 11 - DNA, 35 bp, synthetic construct
  source 1..35: mol_type = other DNA
agttgcggattcgacgcgttgatattagcggccgt

SEQ ID NO: 12 - DNA, 34 bp, synthetic construct
  source 1..34: mol_type = other DNA
gccgcgttacgttagccggactattcgatgcagc

SEQ ID NO: 13 - DNA, 34 bp, synthetic construct
  source 1..34: mol_type = other DNA
gctgcatcgaatagtccggctaacgtaacgcggc